(19) United States
(12) Patent Application Publication
(10) Pub. No.: US 2026/0093178 A1
(43) Pub. Date: Apr. 2, 2026

(54) POLYMER, METHOD OF PRODUCING THE SAME, RESIST COMPOSITION INCLUDING THE POLYMER, AND PATTERN FORMATION METHOD USING THE RESIST COMPOSITION

(71) Applicant: Samsung Electronics Co., Ltd., Suwon-si (KR)

(72) Inventors: Chanjae AHN, Suwon-si (KR); Myungwoong KIM, Incheon (KR); Minsang KIM, Suwon-si (KR); Beomseok KIM, Suwon-si (KR); Seungjun KIM, Incheon (KR); Hyeji LEE, Incheon (KR); Sungwon CHOI, Suwon-si (KR)

(73) Assignees: Samsung Electronics Co., Ltd., Suwon-si (KR); Inha University Research and Business Foundation, Incheon (KR)

(21) Appl. No.: 19/335,860

(22) Filed: Sep. 22, 2025

(30) Foreign Application Priority Data
Sep. 27, 2024 (KR) 10-2024-0132009

(51) Int. Cl. G03F 7/039; C08G 16/02; H01L 21/027

(52) U.S. Cl. CPC G03F 7/0395; C08G 16/0225; C08G 16/0256; H10P 76/20

(57) ABSTRACT

Provided are a polymer including a first repeating unit represented by Formula 1 and a second repeating unit represented by Formula 2, a method of producing the same, a resist composition including the polymer, and a method of producing a pattern by using the resist composition:

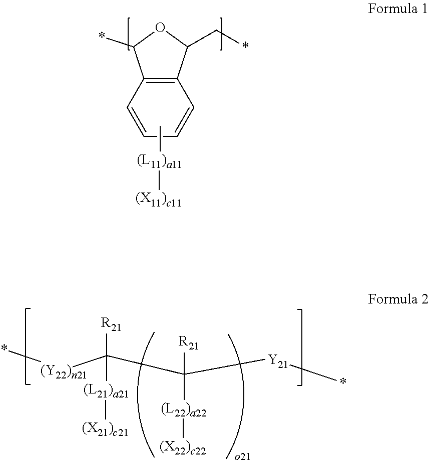

wherein, for descriptions of L₁₁, a11, X₁₁, c11, Y₂₁, Y₂₂, n21, L₂₁, L₂₂, a21, a22, R₂₁, R₂₂, X₂₁, X₂₂, c21, c22 and o21 in Formulae 1 and 2, reference should be made to the specification.

### CROSS-REFERENCE TO RELATED APPLICATION

This application is based on and claims priority under 35 USC § 119 to Korean Patent Application No. 10-2024-0132009, filed on Sep. 27, 2024, in the Korean Intellectual Property Office, the disclosure of which is incorporated by reference herein in its entirety.

### BACKGROUND

### 1. Field

The inventive concepts relate to polymers, methods of producing the same, resist compositions including one or more of the polymers, and pattern formation methods using one or more of the resist compositions.

### 2. Description of the Related Art

In semiconductor manufacturing, resists of which physical properties change in response to light are being used to form fine patterns. Among these resists, chemically amplified resists have been widely used. In the case of chemically amplified resists, an acid formed through a reaction between light and a photoacid generator reacts with a base resin again to change the solubility of the base resin with respect to a developer, thereby enabling patterning.

In particular, when using high-energy rays with relatively very high energy, such as EUV, there is a problem in which the number of photons is significantly smaller even when light of the same energy is irradiated.

### SUMMARY

Some example embodiments provide a polymer capable of providing improved sensitivity and/or resolution, a method of producing the polymer, a resist composition including the polymer, and/or a pattern formation method using the resist composition. Such a polymer having improved sensitivity and/or resolution may be configured to enable a resist composition that can act effectively even when a small amount is used and that can provide improved sensitivity and/or improved resolution.

Additional aspects will be set forth in part in the description which follows and, in part, will be apparent from the description, or may be learned by practice of the presented example embodiments of the inventive concepts.

According to some example embodiments of the inventive concepts, a polymer may include a first repeating unit represented by Formula 1 and a second repeating unit represented by Formula 2:

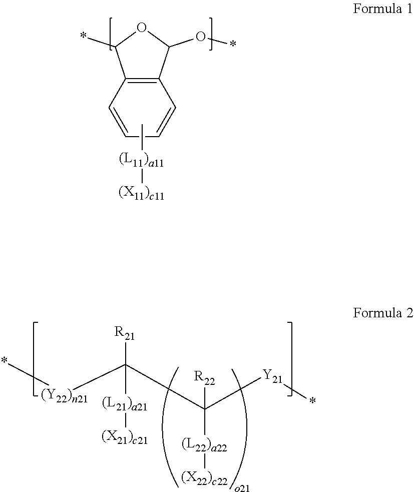

wherein in Formulae 1 and 2,
L₁₁ may be a single bond; O; S; C(═O); C(═O)O; OC(═O); C(═O)NR₁₁; NR₁₁C(═O); S(═O); S(═O)₂O; OS(═O)₂; or a linear, branched or cyclic C₁-C₃₀ divalent hydrocarbon group optionally including a heteroatom,
a11 may be an integer from 1 to 4,
R₁₁ may be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
X₁₁ may be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
c11 may be an integer from 1 to 10,
Formula 1 may optionally include a plurality of X₁₁ based on c11 being greater than 1, adjacent two of the plurality of X₁₁ may be optionally bound to each other to form a ring,
Y₂₁ may be O, C(═O) or C(═O)O,
Y₂₂ may be C(═O) or C(═O)O,
n21 may be 0 or 1,
L₂₁ is a single bond; O; S; C(═O); C(═O)O; OC(═O); C(═O)NR₂₃; NR₂₃C(═O); S(═O); S(═O)₂O; OS(═O)₂; or a linear, branched or cyclic C₁-C₃₀ divalent hydrocarbon group optionally including a heteroatom,
L₂₂ may be a single bond; O; S; C(═O); C(═O)O; OC(═O); C(═O)NR₂₄; NR₂₄C(═O); S(═O); S(═O)₂O; OS(═O)₂; or a linear, branched or cyclic C₁-C₃₀ divalent hydrocarbon group optionally including a heteroatom,
a21 and a22 may each independently be an integer from 1 to 4,
R₂₁ to R₂₄, X₂₁ and X₂₂ may each independently be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
c21 and c22 may each independently be an integer from 1 to 10,
Formula 2 may optionally include a plurality of X₂₁ based on c21 being greater than 1, Formula 2 may optionally include a plurality of X₂₂ based on c22 being greater than 1, and adjacent two of the plurality of X₁₁ and the plurality of X₂₂ may be optionally bound to each other to form a ring,
o21 may be 0 or 1, and
* is a bonding site with a neighboring atom.
L₁₁, L₂₁ and L₂₂ may each independently be a single bond; O; S; C(═O); C(═O)O; OC(═O); C(═O) NH; NHC(═O); S(═O); S(═O)₂; S(═O)₂O; OS(═O)₂; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.
R₂₁ and R₂₂ may each independently be selected from hydrogen; deuterium; a halogen atom; a cyano group; a nitro group; a hydroxyl group; amino group; a carboxylate group; a thiol group; a C₁-C₂₀ alkyl group, a C₃-C₂₀ cycloalkyl group, and a C₆-C₂₀ aryl group,
the C₁-C₂₀ alkyl group, the C₅-C₂₀ cycloalkyl group, and the C₆-C₂₀ aryl group are each independently unsubstituted or substituted with deuterium, a halogen atom, a cyano group, a nitro group, a hydroxyl group, an amino group, a carboxylate group, a thiol group, an ester moiety, a sulfonate moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof. R₁₁, R₂₃ and R₂₄ may each independently be hydrogen, deuterium, a halogen atom, a cyano group, a nitro group, a hydroxyl group, amino group, a carboxylate group, a thiol group, a C₁-C₂₀ alkyl group, a C₁-C₂₀ halogenated alkyl group, a C₅-C₂₀ cycloalkyl group, or a C₆-C₂₀ aryl group.
X₁₁, X₂₁ and X₂₂ may each independently be selected from hydrogen; deuterium; a halogen atom; a cyano group; a nitro group; a hydroxyl group; an amino group; a carboxylate group; a thiol group; a linear, branched or cyclic C₁-C₃₀ monovalent hydrocarbon group containing a polar moiety; and a linear, branched or cyclic C₁-C₃₀ monovalent hydrocarbon group not containing a polar moiety. The polar moiety may be one or more selected from a halogen atom, a cyano group, a nitro group, a hydroxyl group, an amino group, a carboxylate group, a thiol group, O, C═O, a sultone moiety, a lactone moiety, an ester moiety, a sulfonate moiety, a carbonate moiety, a carbamate moiety, and a carboxylic anhydride moiety.
X₁₁, X₂₁ and X₂₂ may each independently be selected from hydrogen; deuterium; a halogen atom; a cyano group; a nitro group; a hydroxyl group; an amino group; a carboxylate group; a thiol group; a C₁-C₁₀ alkyl group unsubstituted or substituted with deuterium, a halogen atom, a cyano group, nitro group, a hydroxyl group, an amino group, a carboxylate group, a thiol group, or any combination thereof; and groups represented by Formulae 5-1 to 5-19 below,

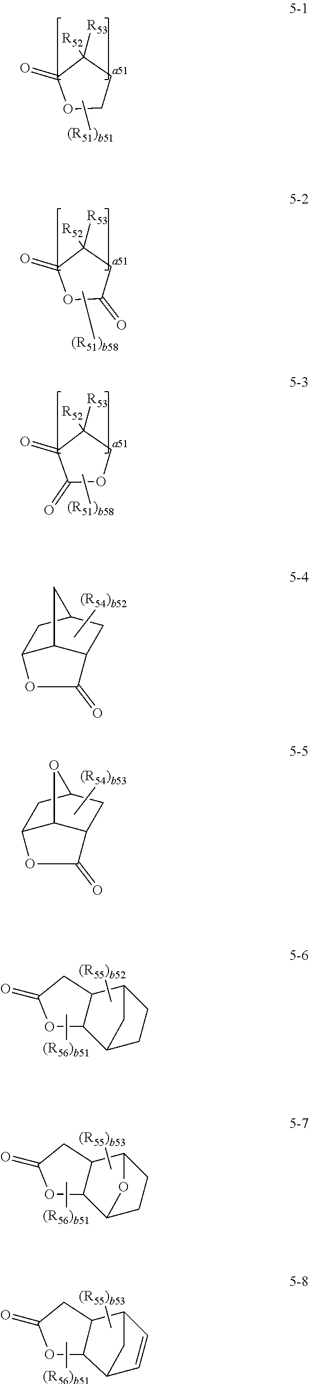

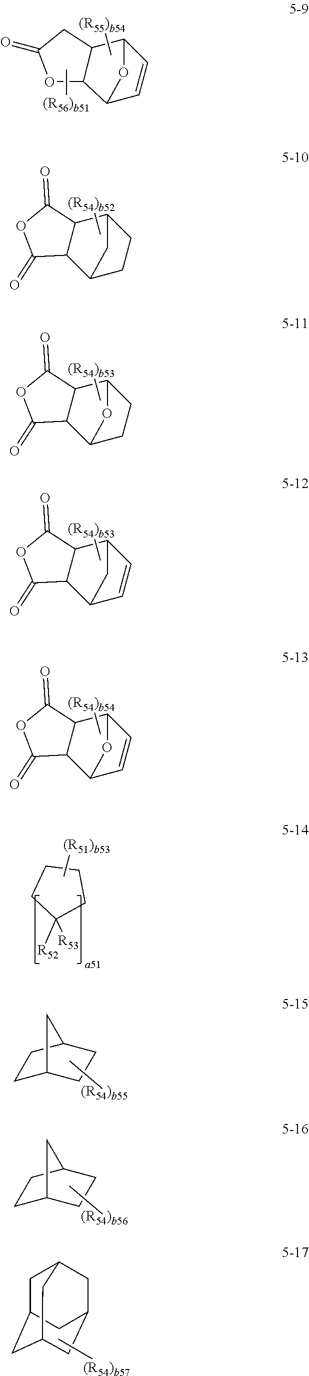

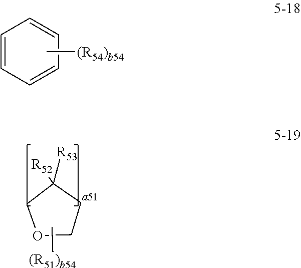

wherein in Formulae 5-1 to 5-19: a51 may be an integer from 1 to 3; R₅₁ to R₅₆ may each independently be a bonding site with a neighboring atom, hydrogen, deuterium, a halogen atom, a cyano group, a nitro group, a hydroxyl group, an amino group, a carboxylate group, a thiol group, or a linear, branched or cyclic C₁-C₁₀ monovalent hydrocarbon group optionally including a heteroatom; one of R₅₁ to R₅₃, one of R₅₄, and one of R₅₅ or R₅₆ may each be a bonding site with a neighboring atom; b51 may be an integer from 1 to 4; b52 may be an integer from 1 to 10; b53 may be an integer from 1 to 8; b54 may be an integer from 1 to 6; b55 may be an integer from 1 to 12; b56 may be an integer from 1 to 14; b57 may be an integer from 1 to 16; and b58 may be 1 or 2.
R₅₁ to R₅₆ may each independently be selected from a bonding site with a neighboring atom, hydrogen, deuterium, a halogen atom, a cyano group, a nitro group, a hydroxyl group, an amino group, a carboxylate group, a thiol group, a C₁-C₁₀ alkyl group, a C₃-C₁₀ cycloalkyl group, a C₁-C₁₀ alkoxy group, a C₃-C₁₀ cycloalkoxy group and groups represented by Formulae 6-1 to 6-12 below,

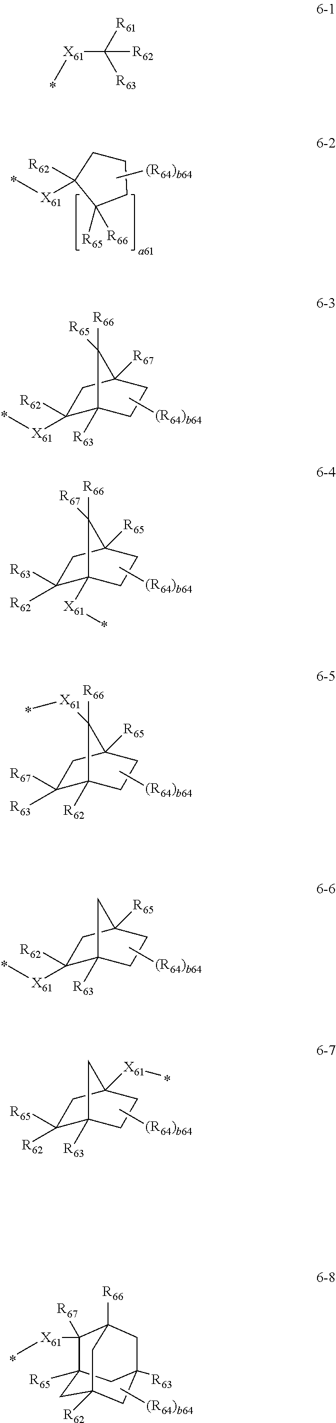

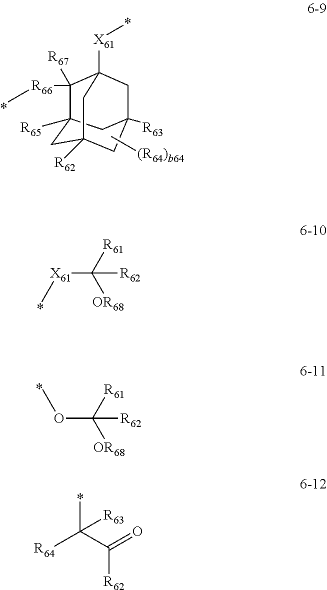

wherein in Formulae 6-1 to 6-12: X₆₁ may be an ester moiety, a sulfonate moiety, a carbonate moiety or a carbamate moiety; a61 may be an integer from 1 to 3; R₆₁ and R₆₈ may each independently be a C₁-C₁₀ alkyl group, a C₃-C₁₀ cycloalkyl group, a C₁-C₁₀ alkoxy group, or a C₃-C₁₀ cycloalkoxy group; R₆₂ to R₆₇ may each independently be hydrogen, deuterium, a halogen atom, a cyano group, a nitro group, a hydroxyl group, an amino group, a carboxylate group, a thiol group, a C₁-C₁₀ alkyl group, a C₃-C₁₀ cycloalkyl group, a C₁-C₁₀ alkoxy group, or a C₃-C₁₀ cycloalkoxy group; two adjacent groups of R₆₁ to R₆₈ may be optionally bound to each other to form a ring; b64 may be an integer from 1 to 10; and * is a bonding site with a neighboring atom.

The first repeating unit may be selected from the following Group I, and the second repeating unit is selected from the following Group II:

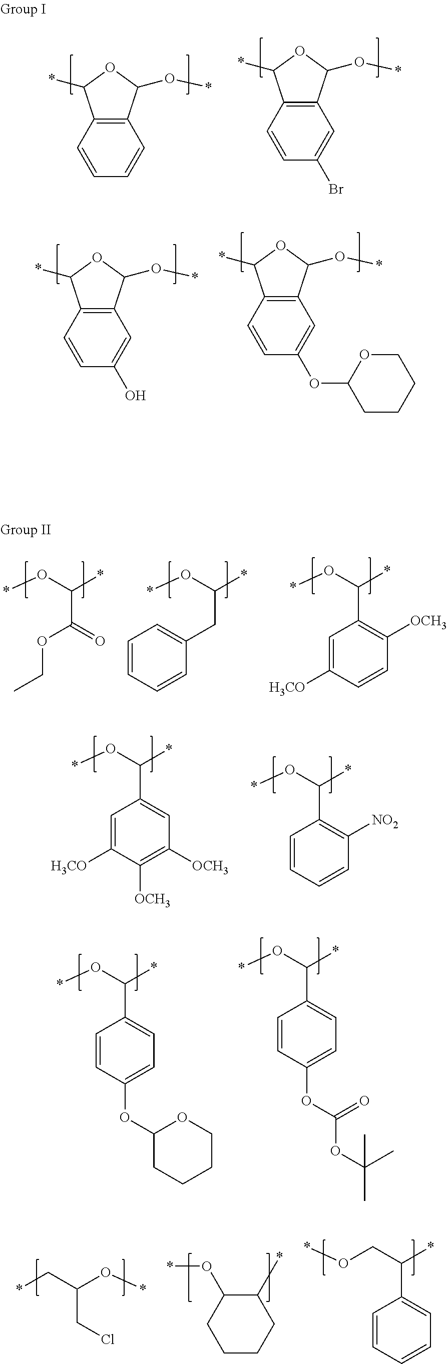

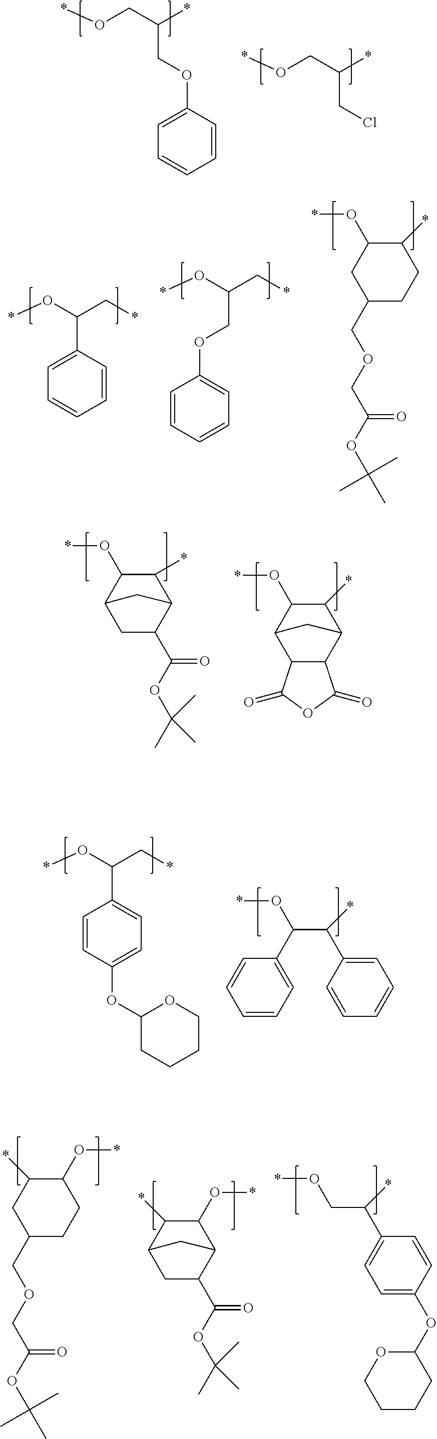

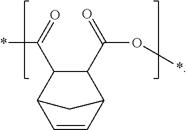

The polymer may further include a third repeating unit represented by Formula 3:

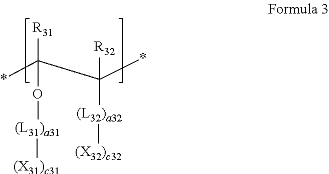

wherein in Formula 3,
L₃₁ may be a single bond; O; S; C(═O); C(═O)O; OC(═O); C(═O)NR₃₃; NR₃₃C(═O); S(═O); S(═O)₂O; OS(═O)₂; or a linear, branched or cyclic C₁-C₃₀ divalent hydrocarbon group optionally including a heteroatom,
L₃₂ may be a single bond; O; S; C(═O); C(═O)O; OC(═O); C(═O)NR₃₄; NR₄₃C(═O); S(═O); S(═O)₂O; OS(═O)₂; or a linear, branched or cyclic C₁-C₃₀ divalent hydrocarbon group optionally including a heteroatom,
a31 and a32 may each independently be an integer from 1 to 4,
R₃₁ to R₃₄, X₃₁ and X₃₂ may each independently be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylate anhydride moiety; or a linear, branched or cyclic C₁-C₃₀ monovalent hydrocarbon group optionally including a heteroatom,
c31 and c32 may each independently be an integer from 1 to 10,
Formula 3 may optionally include a plurality of X₃₁ based on c31 being greater than 1, Formula 3 may optionally include a plurality of X₃₂ based on c32 being greater than 1, and adjacent two of the plurality of X₃₁ and the plurality of X₃₂ may be optionally bound to each other to form a ring, and
* is a bonding site with a neighboring atom.

The third repeating unit may be selected from the following Group III:

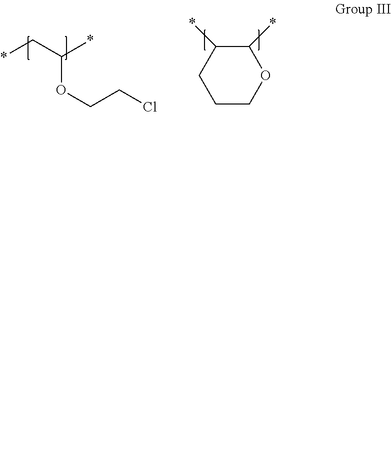

According to some example embodiments, a method of producing a polymer may include: polymerizing a mixture by using an acid catalyst, the mixture including a first monomer represented by Formula 1A; and at least one second monomer selected from an aldehyde, an oxirane, a carboxylic anhydride, and a lactone:

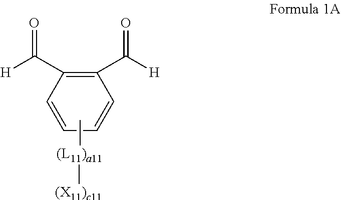

wherein in Formula 1A,
L₁₁ may be a single bond; O; S; C(═O); C(═O)O; OC(═O); C(═O)NR₁₁; NR₁₁C(═O); S(═O); S(═O)₂O; OS(═O)₂; or a linear, branched or cyclic C₁-C₃₀ divalent hydrocarbon group optionally including a heteroatom,
a11 may be an integer from 1 to 4,
R₁₁ may be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
X₁₁ may be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
c11 may be an integer from 1 to 10, and

Formula 1 may optionally include a plurality of X₁₁ based on c11 being greater than 1, adjacent two of the plurality of X₁₁ may be optionally bound to each other to form a ring.

The mixture may further include at least one third monomer selected from vinyl ethers.

The polymerizing may further utilize a RAFT agent.

According to some example embodiments, a resist composition may include the polymer and a solvent.

The resist composition may further include a photoacid generator.

The photoacid generator may be represented by Formula 7:

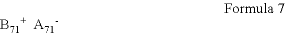

wherein in Formula 7,
B₇₁₊ may be represented by Formula 7A, and A₇₁₋ may be represented by any one of Formulae 7B to 7D, and
B₇₁₊ and A₇₁₋ may be optionally linked via a carbon-carbon covalent bond,

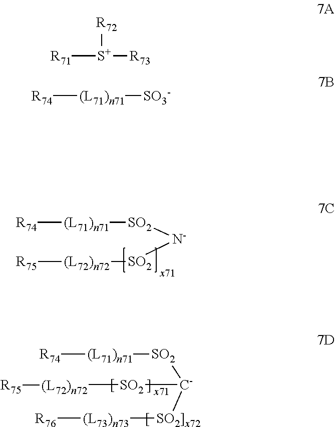

wherein in Formulae 7A to 7D,
L₇₁ to L₇₃ may each independently be a single bond or CRR′,
R and R′ may each independently be hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group or a C₃-C₃₀ cycloalkoxy group,
n71 to n73 may each independently be 1, 2 or 3,
x71 and x72 may each independently be 0 or 1,
R₇₁ to R₇₃ may each independently be a linear, branched or cyclic C₁-C₃₀ monovalent hydrocarbon group optionally including a heteroatom,
adjacent two of R₇₁ to R₇₃ may be optionally bound to each other to form a condensed ring, and
R₇₄ to R₇₆ may each independently be hydrogen; a halogen atom; or a linear, branched or cyclic C₁-C₃₀ monovalent hydrocarbon group optionally including a heteroatom.

The resist composition may further include a quencher.

The quencher may be represented by Formula 8:

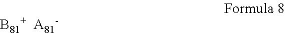

wherein in Formula 8,
B₈₁₊ may be represented by any one of Formulae 8A to 8C, and A₈₁₋ may be represented by any one of Formulae 8D to 8F,
B₈₁₊ and A₈₁₋ may be optionally linked via a carbon-carbon covalent bond,

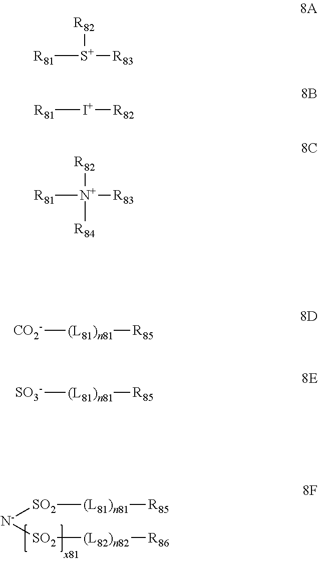

wherein in Formulae 8A to 8F,
L₈₁ and L₈₂ may each independently be a single bond or CRR′,
R and R′ may each independently be hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group or a C₃-C₃₀ cycloalkoxy group,
n81 and n82 may each independently be 1, 2 or 3,
x81 may be 0 or 1,
R₈₁ to R₈₄ may each independently be a linear, branched or cyclic C₁-C₃₀ monovalent hydrocarbon group optionally including a heteroatom,
adjacent two of R₈₁ to R₈₄ may be optionally bound to each other to form a condensed ring, and
R₈₅ and R₈₆ may each independently be hydrogen; a halogen atom; or a linear, branched or cyclic C₁-C₃₀ monovalent hydrocarbon group optionally including a heteroatom.

According to some example embodiments, a method of forming a pattern may include applying the resist composition onto a substrate to form a resist film; exposing at least a portion of the resist film to high-energy rays; and developing the exposed resist film based on using a developer.

The exposing may be performed based on irradiating at least the portion of the resist film with at least one of ultraviolet rays, deep ultraviolet (DUV) rays, extreme ultraviolet (EUV) rays, X-rays, γ-rays, electron beams (Ebs) or α particle beams.

The exposed resist film may include an exposed portion and an unexposed portion, and the exposed portion may be removed during the developing.

According to some example embodiments of the inventive concepts, a resist composition includes the polymer and a solvent.

According to some example embodiments of the inventive concepts, a pattern formation method includes applying the resist composition to form a resist film, exposing at least a portion of the resist film to high-energy rays, and developing the exposed resist film using a developer.

### BRIEF DESCRIPTION OF THE DRAWINGS

The above and other aspects, features, and advantages of certain embodiments of the inventive concepts will be more apparent from the following description taken in conjunction with the accompanying drawings, in which:

FIG. 1 is a flowchart illustrating a method of forming a pattern, according to some example embodiments;

FIGS. 2A, 2B, and 2C are cross-sectional side views showing a method of forming a pattern, according to some example embodiments;

FIGS. 3A, 3B, 3C, 3D, and 3E are cross-sectional side views showing a method of forming a patterning structure, according to some example embodiments; and

FIGS. 4A, 4B, 4C, 4D, and 4E are cross-sectional side views showing a method of forming a semiconductor device, according to some example embodiments.

### DETAILED DESCRIPTION

Reference will now be made in detail to some example embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

As the inventive concepts allow for various changes and numerous various example embodiments, some example embodiments will be illustrated in the drawings and described in detail in the written description. However, this is not intended to limit the inventive concepts to particular modes of practice, and it is to be appreciated that all modifications, equivalents, and substitutes that do not depart from the spirit and technical scope of the inventive concepts are encompassed in the inventive concepts. In describing the inventive concepts, when it is determined that the specific description of the known related art unnecessarily obscures the gist of the inventive concepts, the detailed description thereof will be omitted.

Although the terms “first”, “second”, “third”, and the like may be used herein to describe various elements, these terms are only used to distinguish one element from another and the order, type, or the like of the elements are not limited thereby.

A portion of a layer, film, region, plate, or the like described as being “on” or “above” another portion as used herein, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Unless explicitly described to the contrary, it is to be understood that the terms such as “including” and “having” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

The expression “Cₓ-C_{y}” used herein refers to the case where the number of carbon atoms constituting a substituent is in a range of x to y, wherein x and y may each be any natural number. For example, the expression “C₁-C₆” refers to the case where the number of carbon atoms constituting a substituent is in a range of 1 to 6, and the expression “C₆-C₂₀” refers to the case where the number of carbon atoms constituting a substituent is in a range of 6 to 20.

The term “monovalent hydrocarbon group” used herein refers to a monovalent residue derived from an organic compound including carbon and hydrogen or a derivative thereof, and specific examples thereof include a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cycloaliphatic hydrocarbon group (a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); a monovalent unsaturated aliphatic hydrocarbon group (an alkenyl group or an alkynyl group) (e.g., an allyl group); a monovalent unsaturated cycloaliphatic hydrocarbon group (a cycloalkenyl group) (e.g., 3-cyclohexenyl); an aryl group (e. g., a phenyl group, a 1-naphthyl group, and a 2-naphthyl group); an arylalkyl group (e. g., a benzyl group and a diphenylmethyl group); a heteroatom-including monovalent hydrocarbon group (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group), or any combination thereof. Additionally, some of hydrogens in these groups may be substituted with a moiety including one or more heteroatoms such as oxygen, sulfur, nitrogen, phosphorous or halogen atoms, or some of carbons in these groups may be replaced by a moiety including one or more heteroatoms such as oxygen, sulfur, nitrogen, or phosphorous, and thus these groups may include a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, or a carboxylic anhydride moiety.

The term “divalent hydrocarbon group” as used herein is a divalent residue and refers to a system in which any one hydrogen atom of the monovalent hydrocarbon group is replaced by a bonding site with a neighboring atom. The divalent hydrocarbon group may include, for example, a linear or branched alkylene group, a cycloalkylene group, an alkenylene group, an alkynylene group, a cycloalkylene group, an arylene group, a group in which some carbon atoms thereof are replaced with a heteroatom, and the like.

The term “alkyl group” as used herein refers to a linear or branched saturated aliphatic monovalent hydrocarbon group, and examples thereof may include a methyl group, an ethyl group, a propyl group, an isobutyl group, a sec-butyl group, a tert-butyl group, a pentyl group, an iso-amyl group, and a hexyl group. The term “alkylene group” as used herein refers to a linear or branched saturated aliphatic divalent hydrocarbon group, and examples thereof may include a methylene group, an ethylene group, a propylene group, a butylene group, and an isobutylene group.

The term “halogenated alkyl group” as used herein refers to a group in which one or more substituents of an alkyl group are substituted with a halogen atom, and examples thereof may include CF₃. The halogen atom may be F, Cl, Br or I.

The term “alkoxy group” as used herein refers to a monovalent group represented by Formula —OA₁₀₁, wherein A₁₀₁ is an alkyl group. Specific examples thereof may include a methoxy group, an ethoxy group, an isopropyloxy group, and the like.

The term “alkylthio group” as used herein refers to a monovalent group represented by Formula —SA₁₀₁, wherein A₁₀₁ is an alkyl group.

The term “halogenated alkoxy group” as used herein refers to a group in which one or more hydrogen atoms of an alkoxy group are substituted with a halogen atom, and specific examples thereof may include —OCF₃ and the like.

The term “halogenated alkylthio group” as used herein refers to a group in which one or more hydrogen atoms of an alkylthio group are substituted with a halogen atom, and specific examples thereof may include —SCF₃ and the like.

The term “cycloalkyl group” as used herein refers to a monovalent saturated hydrocarbon cyclic group, and specific examples thereof may include monocyclic groups, such as a cyclopropyl group, a cyclobutyl group, a cyclopentyl group, a cyclohexyl group, and a cycloheptyl group, and polycyclic condensed cyclic groups, such as a norbornyl group and an adamantyl group. The term “cycloalkylene group” as used herein refers to a divalent saturated hydrocarbon cyclic group, and specific examples thereof may include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group represented by Formula —OA₁₀₂, wherein A₁₀₂ is a cycloalkyl group. Specific examples thereof may include a cyclopropoxy group, a cyclobutoxy group, and the like.

The term “cycloalkylthio group” as used herein refers to a monovalent group represented by Formula —SA₁₀₂, where A₁₀₂ is a cycloalkyl group.

The term “heterocycloalkyl group” as used herein refers to a group in which some carbon atoms of the cycloalkyl group are substituted with a moiety including one or more heteroatoms, such as oxygen, sulfur, or nitrogen, and the heterocycloalkyl group may specifically include an ether bond, an ester bond, a sulfonate bond, a carbonate, a lactone ring, a sultone ring, or a carboxylic anhydride moiety. The term “heterocycloalkylene group” as used herein refers to a group in which some carbon atoms of the cycloalkylene group are substituted with a moiety including one or more heteroatoms such as oxygen, sulfur, or nitrogen.

The term “heterocycloalkoxy group” as used herein refers to a monovalent group represented by Formula —OA₁₀₃, wherein A₁₀₃ is a heterocycloalkyl group.

The term “heterocycloalkylthio group” as used herein refers to a monovalent group represented by Formula of —SA₁₀₃, wherein A₁₀₃ is a heterocycloalkyl group.

The term “alkenyl group” as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including one or more carbon-carbon double bonds.

The term “cycloalkenyl group” as used herein refers to a monovalent unsaturated hydrocarbon cyclic group including at least one carbon-carbon double bond. The term “cycloalkenylene group” as used herein refers to a divalent unsaturated hydrocarbon cyclic group including at least one carbon-carbon double bond.

The term “heterocycloalkenyl group” as used herein refers to a group in which some carbon atoms of the cycloalkenyl group are substituted with a moiety including a heteroatom such as oxygen, sulfur, or nitrogen. The term “heterocycloalkenylene group” as used herein refers to a group in which some carbon atoms of the cycloalkenylene group are substituted with a moiety including a heteroatom such as oxygen, sulfur, or nitrogen.

The term “alkynyl group” as used herein refers to a linear or branched monovalent unsaturated aliphatic hydrocarbon group including one or more carbon-carbon triple bonds.

The term “aryl group” as used herein refers to a monovalent group including a carbocyclic aromatic system, and examples thereof include a phenyl group, a naphthyl group, an anthracenyl group, a phenanthrenyl group, a pyrenyl group, and a chrysenyl group. The term “arylene group” as used herein refers to a divalent group including a carbocyclic aromatic system.

The term “aryloxy group” as used herein refers to a monovalent group represented by Formula —OA₁₀₄, where A₁₀₄ is an aryl group.

The term “arylthio group” as used herein refers to a monovalent group represented by Formula —SA₁₀₄, where A₁₀₄ is an aryl group.

The term “heteroaryl group” as used herein refers to a monovalent group including a heterocyclic aromatic system, and examples thereof include a pyridinyl group, a pyrimidinyl group, and a pyrazinyl group. The term “heteroarylene group” as used herein refers to a divalent group including a heterocyclic aromatic system.

The term “heteroaryloxy group” as used herein refers to a monovalent group represented by Formula —OA₁₀₅, where A₁₀₅ is a heteroaryl group.

The term “heteroarylthio group” as used herein refers to a monovalent group represented by Formula —SA₁₀₅, where A₁₀₅ is a heteroaryl group.

The term “arylalkyl group” as used herein refers to a group in which a monovalent group having a carbocyclic aromatic system is substituted on an alkyl group, and specific examples include a benzyl group, a diphenylmethyl group, and the like.

The term “heteroarylalkyl group” as used herein refers to a group in which a monovalent group having a heterocyclic aromatic system is substituted on an alkyl group.

The term “heterocyclic group” as used herein refers to a monocyclic or polycyclic group having 1 to 60 carbon atoms and containing at least one heteroatom, and is a group including monovalent, divalent, trivalent, etc.

The term “substituent” as used herein includes deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group; and
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and C₁-C₂₀ heteroarylthio group, each being substituted with deuterium, a halogen atom, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, or any combination thereof; or any combination thereof.

In order to clearly explain the present inventive concepts in the drawings, parts that are not related to the description are omitted, and similar parts are given similar reference numerals throughout the specification. In the flowchart described with reference to the drawings, the order of operations may be changed, several operations may be merged, certain operations may be divided, and certain operations may not be performed.

Additionally, expressions written in the singular may be interpreted as singular or plural, unless explicit expressions such as “one” or “single” are used. Terms containing ordinal numbers, such as first, second, etc., may be used to describe various elements, but the elements are not limited by these terms. These terms may be used for the purpose of distinguishing one component from another.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

Hereinafter, some example embodiments will be described in detail with reference to the accompanying drawings, wherein like reference numerals denote substantially the same or corresponding components throughout the drawings, and a redundant description thereof will be omitted. In the drawings, thicknesses of various layers and regions are enlarged for clarity. Also, in the drawings, the thicknesses of some layers and regions are exaggerated for convenience of description. Meanwhile, embodiments set forth hereinafter are merely for illustrative purposes, and various changes may be made therein.

### [Polymer]

A polymer according to some example embodiments may include a first repeating unit represented by Formula 1 and a second repeating unit represented by Formula 2:

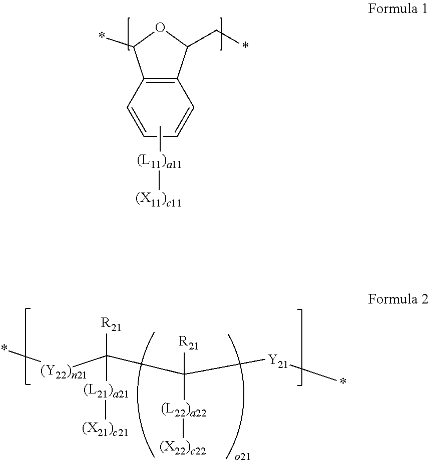

wherein in Formulae 1 and 2,
L₁₁ may be a single bond; O; S; C(═O); C(═O)O; OC(═O); C(═O)NR₁₁; NR₁₁C(═O); S(═O); S(═O)₂O; OS(═O)₂; or a linear, branched or cyclic C₁-C₃₀ divalent hydrocarbon group optionally including a heteroatom,
a11 may be an integer from 1 to 4,
R₁₁ may be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
X₁₁ may be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
c11 may be an integer from 1 to 10,
Formula 1 may optionally include a plurality of X₁₁ based on c11 being greater than 1, and adjacent two of the plurality of X₁₁ may be optionally bound to each other to form a ring,
Y₂₁ may be O, C(═O) or C(═O)O,
Y₂₂ may be C(═O) or C(═O)O,
n21 may be 0 or 1,
L₂₁ may be a single bond; O; S; C(═O); C(═O)O; OC(═O); C(═O)NR₂₃; NR₂₃C(═O); S(═O); S(═O)₂O; OS(═O)₂; or a linear, branched or cyclic C₁-C₃₀ divalent hydrocarbon group optionally including a heteroatom,
L₂₂ may be a single bond; O; S; C(═O); C(═O)O; OC(═O); C(═O)NR₂₄; NR₂₄C(═O); S(═O); S(═O)₂O; OS(═O)₂; or a linear, branched or cyclic C₁-C₃₀ divalent hydrocarbon group optionally including a heteroatom,
a21 and a22 may each independently be an integer from 1 to 4,
R₂₁ to R₂₄ and X₂₁ and X₂₂ may each independently be hydrogen;
deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
c21 and c22 may each independently be an integer from 1 to 10,
Formula 2 may optionally include a plurality of X₂₁ based on c21 being greater than 1, Formula 2 may optionally include a plurality of X₂₂ based on c22 being greater than 1, and adjacent two of the plurality of X₂₁ and the plurality of X₂₂ may be optionally bound to each other to form a ring,
o21 may be 0 or 1, and
* is a bonding site with a neighboring atom.

For example, in Formulae 1 and 2, L₁, L₂₁ and L₂₂ may each independently be: a single bond; O; S; C(═O); C(═O)O; OC(═O); C(═O) NH; NHC(═O); S(═O); S(═O)₂; S(═O)₂O; OS(═O)₂; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

Specifically, in Formulae 1 and 2, L₁₁, L₂₁ and L₂₂ may each independently be selected from: a single bond; O; C(═O); C(═O)O; OC(═O); C(═O) NH; NHC(═O); and C₁-C₂₀ alkylene group, a C₅-C₂₀ cycloalkylene group, a C₅-C₂₀ heterocycloalkylene group, a C₂-C₂₀ alkenylene group, a C₃-C₂₀ cycloalkenylene group, a C₃-C₂₀ heterocycloalkenylene group, a C₆-C₂₀ arylene group, and a C₁-C₂₀ heteroarylene group, each unsubstituted or substituted with deuterium, a halogen atom, a cyano group, a nitro group, a hydroxyl group, an amino group, a carboxylate group, a thiol group, an ester moiety, a sulfonate moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₃₀ aryl group, or any combination thereof.

More specifically, in Formulae 1 and 2, L₁₁, L₂₁ and L₂₂ may each independently be selected from: a single bond; O; C(═O); C(═O)O; OC(═O); C(═O) NH; NHC(═O); and a C₁-C₂₀ alkylene group, a C₃-C₂₀ cycloalkylene group, a C₃-C₂₀ heterocycloalkylene group, a phenylene group and a naphthylene group, each unsubstituted or substituted with deuterium, a halogen atom, a C₁-C₂₀ alkyl group, a C₁-C₂₀ halogenated alkyl group, a C₁-C₂₀ alkoxy group, a phenyl group, a naphthyl group, or any combination thereof.

In Formula 1, a11 indicates the number of repetitions of L₁₁.

In Formula 2, a21 and a22 represent the number of repetitions of L₂₁ and L₂₂, respectively.

For example, in Formulae 1 and 2, a11, a21, and a22 may each independently be an integer from 1 to 3.

Specifically, in Formulae 1 and 2, a11, a21 and a22 may each independently be 1.

For example, in Formula 2, R₂₁ and R₂₂ may each independently be selected from: hydrogen; deuterium; a halogen atom; a cyano group; a nitro group; a hydroxyl group; an amino group; a carboxylate group; a thiol group; a C₁-C₂₀ alkyl group, a C₃-C₂₀ cycloalkyl group, and a C₆-C₂₀ aryl group. The C₁-C₂₀ alkyl group, the C₃-C₂₀ cycloalkyl group, and the C₆-C₂₀ aryl group may each independently be unsubstituted or substituted with a deuterium, a halogen atom, a cyano group, a nitro group, a hydroxyl group, an amino group, a carboxylate group, a thiol group, an ester moiety, a sulfonate moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₅-C₂₀ cycloalkyl group, a C₃-C₂₀ cycloalkoxy group, a C₆-C₂₀ aryl group, or any combination thereof.

Specifically, in Formula 2, R₂₁ and R₂₂ may each independently be selected from: hydrogen; deuterium; a halogen atom; a cyano group; a nitro group; a hydroxyl group; an amino group; a carboxylate group; a thiol group; and a C₁-C₂₀ alkyl group unsubstituted or substituted with deuterium, a halogen atom, a cyano group, a nitro group, an amino group, a carboxylate group, a thiol group, or any combination thereof.

More specifically, in Formula 2, R₂₁ and R₂₂ may each independently be H, D, F, CH₃, CH₂F, CHF₂, CF₃, CH₂CH₃, CHFCH₃, CHFCH₂F, CHFCHF₂, CHFCF₃, CF₂CH₃, CF₂CH₂F, CF₂CHF₂, CF₂CF₃, Cl, CH₂Cl, CHCl₂, CCl₃, CHClCH₃, CHClCH₂Cl, CHClCHCl₂, CHClCCl₃, CCl₂CH₃, CCl₂CH₂Cl, CCl₂CHCl₂, or CCl₂CCl₃.

For example, in Formulae 1 and 2, R₁₁, R₂₃, and R₂₄ may each independently be hydrogen, deuterium, a halogen atom, a cyano group, a nitro group, a hydroxyl group, an amino group, a carboxylate group, a thiol group, a C₁-C₂₀ alkyl group, a C₁-C₂₀ halogenated alkyl group, a C₃-C₂₀ cycloalkyl group, or a C₆-C₂₀ aryl group.

For example, in Formulae 1 and 2, X₁₁, X₂₁ and X₂₂ are each independently selected from: hydrogen; deuterium; a halogen atom; a cyano group; a nitro group; a hydroxyl group; an amino group; a carboxylate group; a thiol group; a linear, branched or cyclic C₁-C₃₀ monovalent hydrocarbon group containing a polar moiety; and a linear, branched or cyclic C₁-C₃₀ monovalent hydrocarbon group not containing a polar moiety (e.g., not containing any polar moiety);

Wherein the polar moiety may be at least one (e.g., one or more) selected from: a halogen atom, a cyano group, a nitro group, a hydroxyl group, an amino group, a carboxylate group, a thiol group, O, C═O, a sultone moiety, a lactone moiety, an ester moiety, a sulfonate moiety, a carbonate moiety, a carbamate moiety, and a carboxylic anhydride moiety.

Specifically, in Formulae 1 and 2, X₁₁, X₂₁ and X₂₂ may each independently be selected from: hydrogen; deuterium; a halogen atom; a cyano group; a nitro group; a hydroxyl group; an amino group; a carboxylate group; a thiol group; a C₁-C₁₀ alkyl group unsubstituted or substituted with deuterium, a halogen atom, a cyano group, a nitro group, a hydroxyl group, an amino group, a carboxylate group, a thiol group, or any combination thereof; and groups represented by Formulae 5-1 to 5-19:

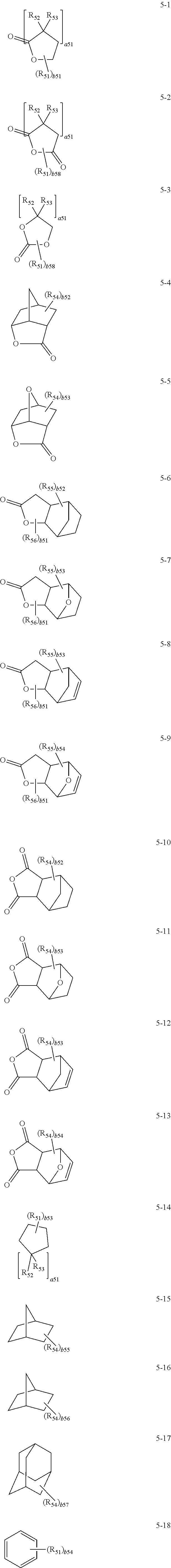

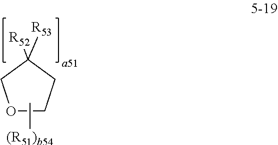

wherein in Formulae 5-1 to 5-19,
a51 may be an integer from 1 to 3;
R₅₁ to R₅₆ may each independently be a bonding site with a neighboring atom, hydrogen, deuterium, a halogen atom, a cyano group, a nitro group, a hydroxyl group, an amino group, a carboxylate group, a thiol group, or a linear, branched or cyclic C₁-C₁₀ monovalent hydrocarbon group optionally including a heteroatom,
one of R₅₁ to R₅₃, one of R₅₄, and one of R₅₅ or R₅₆ are each a bonding site with a neighboring atom,
b51 may be an integer from 1 to 4,
b52 may be an integer from 1 to 10,
b53 may be an integer from 1 to 8,
b54 may be an integer from 1 to 6,
b55 may be an integer from 1 to 12,
b56 may be an integer from 1 to 14,
b57 may be an integer from 1 to 16, and
b58 may be 1 or 2.

For example, in Formulae 5-1 to 5-19, R₅₁ to R₅₆ may each independently be selected from a bonding site with a neighboring atom, hydrogen, deuterium, a halogen atom, a cyano group, a nitro group, a hydroxyl group, an amino group, a carboxylate group, a thiol group, a C₁-C₁₀ alkyl group, a C₃-C₁₀ cycloalkyl group, a C₁-C₁₀ alkoxy group, a C₃-C₁₀ cycloalkoxy group, and groups represented by Formulae 6-1 to 6-12:

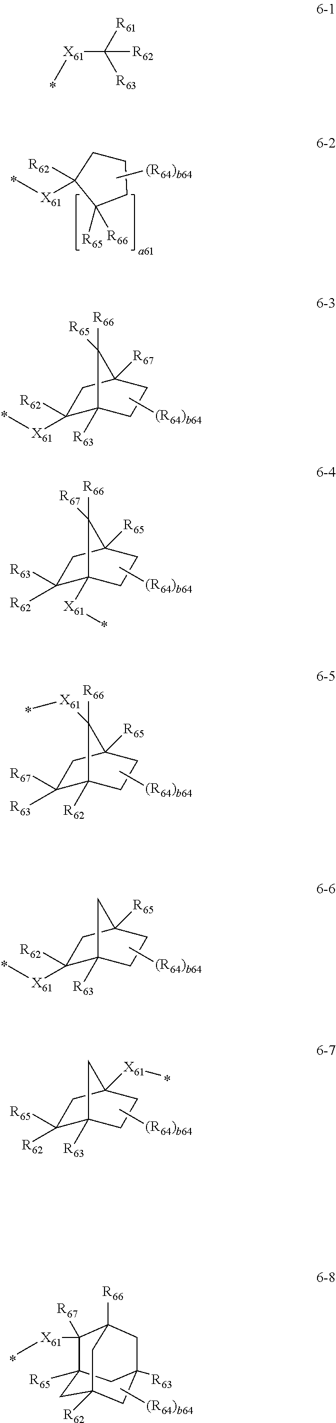

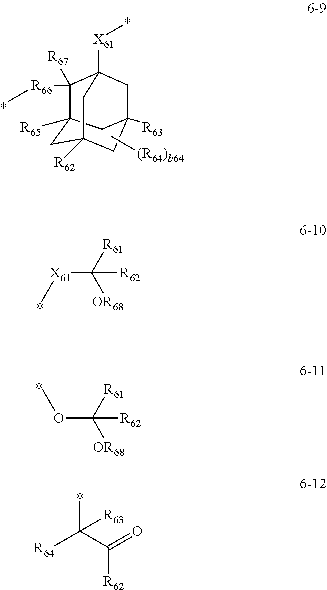

wherein in Formulae 6-1 to 6-12,
X₆₁ may be an ester moiety, a sulfonate moiety, a carbonate moiety, or a carbamate moiety;
a61 may be an integer from 1 to 3;
R₆₁ and R₆₈ may each independently be a C₁-C₁₀ alkyl group, a C₃-C₁₀ cycloalkyl group, a C₁-C₁₀ alkoxy group, or a C₃-C₁₀ cycloalkoxy group,
R₆₂ to R₆₇ may each independently be hydrogen, deuterium, a halogen atom, a cyano group, a nitro group, a hydroxyl group, an amino group, a carboxylate group, a thiol group, a C₁-C₁₀ alkyl group, a C₃-C₁₀ cycloalkyl group, a C₁-C₁₀ alkoxy group, or a C₃-C₁₀ cycloalkoxy group,
adjacent two groups of R₆₁ to R₆₈ may be optionally bound to each other to form a ring,
b64 may be an integer from 1 to 10, and
* is a bonding site with a neighboring atom.

For example, in Formulae 6-1 to 6-12, X₆₁ may be an ester moiety or a carbonate moiety.

Specifically, in Formulae 5-1 to 5-19, R₅₁ to R₅₆ may each independently be selected from a bonding site with a neighboring atom, hydrogen, deuterium, a halogen atom, a cyano group, a nitro group, a hydroxyl group, an amino group, a carboxylate group, a thiol group, a C₁-C₁₀ alkyl group, a C₃-C₁₀ cycloalkyl group, a C₁-C₁₀ alkoxy group, a C₃-C₁₀ cycloalkoxy group, and groups represented by Formulae 6-21 to 6-47:

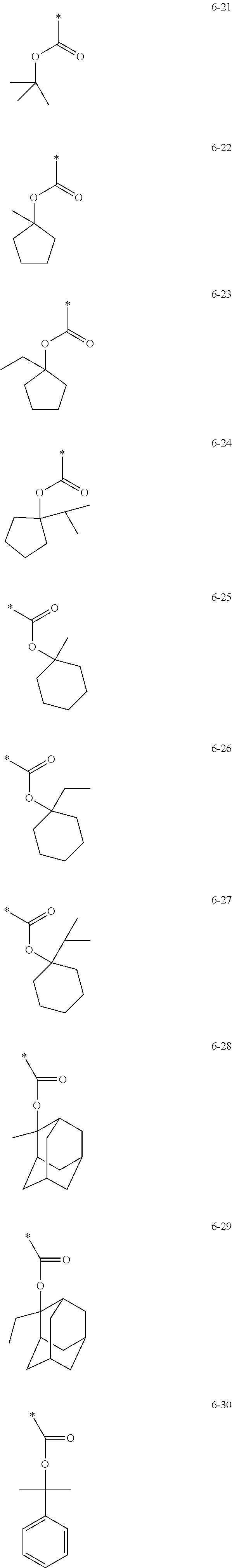

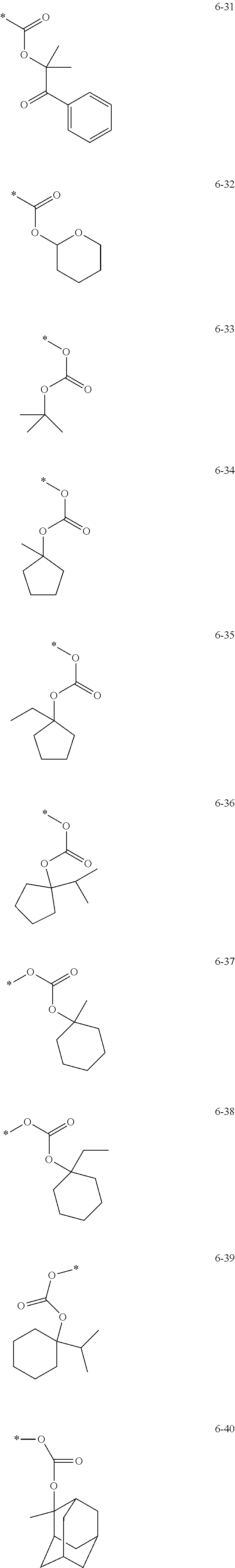

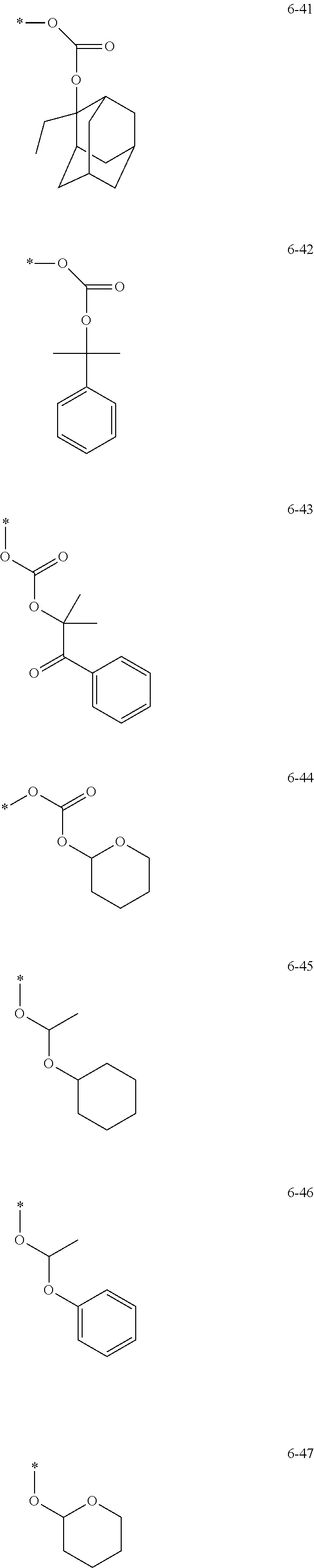

wherein in Formulae 6-21 to 6-47,
* is a bonding site with a neighboring atom.

In some example embodiments, the first repeating unit may be selected from the following Group I:

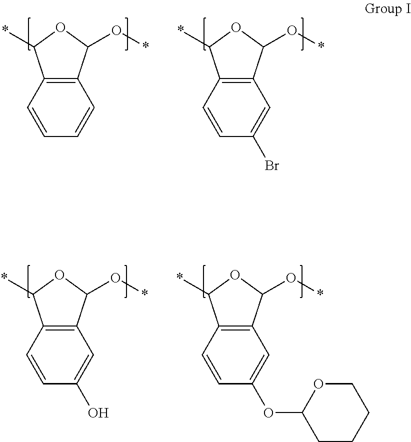

In some example embodiments, the second repeating unit may be selected from the following Group II:

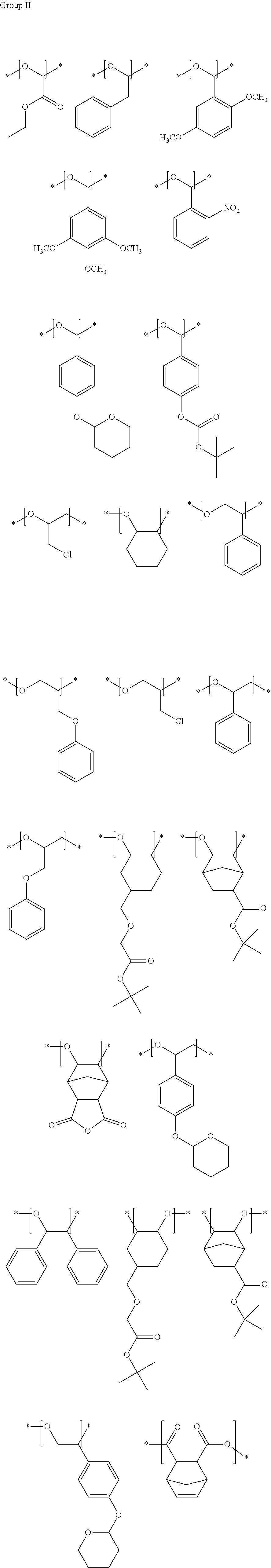

In some example embodiments, the polymer may further include a third repeating unit represented by Formula 3:

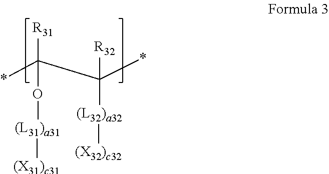

wherein in Formula 3,
L₃₁ may be a single bond; O; S; C(═O); C(═O)O; OC(═O); C(═O)NR₃₃; NR₃₃C(═O); S(═O); S(═O)₂O; OS(═O)₂; or a linear, branched or cyclic C₁-C₃₀ divalent hydrocarbon group optionally including a heteroatom,
L₃₂ may be a single bond; O; S; C(═O); C(═O)O; OC(═O); C(═O)NR₃₄; NR₄₃C(═O); S(═O); S(═O)₂O; OS(═O)₂; or a linear, branched or cyclic C₁-C₃₀ divalent hydrocarbon group optionally including a heteroatom,
a31 and a32 may each independently be an integer from 1 to 4,
R₃₁ to R₃₄, X₃₁ and X₃₂ may each independently be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon optionally including a heteroatom,
c31 and c32 may each independently be an integer from 1 to 10,
Formula 3 may optionally include a plurality of X₃₁ based on c31 being greater than 1, Formula 3 may optionally include a plurality of X₃₂ based on c32 being greater than 1, and adjacent two of the plurality of X₃₁ and the plurality of X₃₂ may be optionally bound to each other to form a ring, and
* is a bonding site with a neighboring atom.

In Formula 3, L₃₁ and L₃₂ may each independently be referred to the description for L₁₁ (e.g., may each independently be the same as L₁₁ as described herein according to some example embodiments).

In Formula 3, a31 and a32 may each independently be referred to the description for a11 (e.g., may each independently be the same as a11 as described herein according to some example embodiments).

In Formula 3, R₃₁ and R₃₂ may each independently be referred to the description for R₂₁ (e.g., may each independently be the same as R₂₁ as described herein according to some example embodiments).

In Formula 3, R₃₃ and R₃₄ may each independently be referred to the description for R₁₁ (e.g., may each independently be the same as R₁₁ as described herein according to some example embodiments).

In Formula 3, X₃₁ and X₃₂ may each independently be referred to the description for X₁₁ (e.g., may each independently be the same as X₁₁ as described herein according to some example embodiments).

In Formula 3, c31 and c32 may each independently be referred to in the description for c11 (e.g., may each independently be the same as c11 as described herein according to some example embodiments).

In some example embodiments, the third repeating unit may be selected from the following Group III:

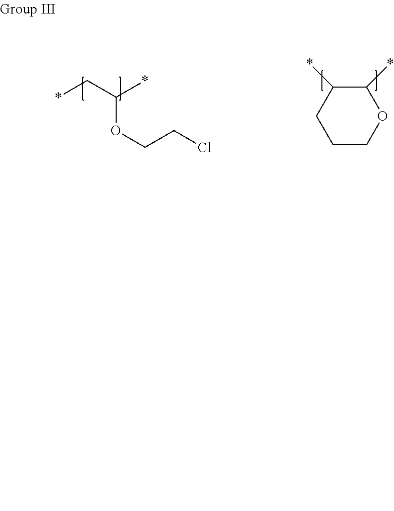

In some example embodiments, the polymer may consist of or comprise the first repeating unit and the second repeating unit. Since, in some example embodiments the polymer does not consist of the first repeating unit (e.g., does not consist of the first repeating unit alone without the second repeating unit), it may have improved thermal stability.

For example, the polymer may include about 1 mol % to about 99 mol %, specifically, about 10 mol % to about 90 mol %, of the first repeating unit, and about 1 mol % to about 99 mol %, specifically, about 10 mol % to about 90 mol %, of the second repeating unit.

In particular, in the polymer, a molar ratio of the first repeating unit to the second repeating unit may be about 5:1 to about 1:5.

In some example embodiments, the polymer may consist of or comprise the first repeating unit, the second repeating unit, and the third repeating unit.

For example, the polymer may include about 1 mol % to about 98 mol %, specifically, about 5 mol % to about 90 mol %, of the first repeating unit, about 1 mol % to about 98 mol %, specifically, about 5 mol % to about 90 mol %, of the second repeating unit, and about 1 mol % to about 98 mol %, specifically, about 5 mol % to about 90 mol %, of the third repeating unit.

In particular, in the polymer, a molar ratio of the first repeating unit to the second repeating unit may be about 5:1 to about 1:5, and a molar ratio of the first repeating unit to the third repeating unit may be about 5:1 to about 1:5.

The polymer may have a weight average molecular weight (Mw) of about 1,000 to about 500,000, specifically, about 3,000 to about 100,000, more specifically, about 5,000 to about 50,000, as measured by gel permeation chromatography using tetrahydrofuran solvent and polystyrene as a standard material.

The polydispersity index (PDI: Mw/Mn) of the polymer may be about 1.0 to about 4.0, specifically, about 1.0 to about 3.5. When the above-described range is satisfied, the possibility of foreign matter remaining on the pattern may be reduced, or the deterioration of the pattern profile may be reduced or minimized. Accordingly, the resist composition may be more suitable for forming a fine pattern. As a result, a resist composition including the polymer may be configured to enable improved reliability (e.g., reduced likelihood of process defects) of fine patterns formed using a pattern formation process (e.g., based on using the resist composition to form a resist film that is exposed to high-energy rays and developed).

The polymer may have its properties changed by high-energy rays. Specifically, as the main chain of the polymer is decomposed, the molecular weight of the polymer decreases, and thus the solubility in a developer may increase.

In addition, since the polymer optionally has an acid-labile group in the main chain, the solubility in a developer may increase as the main chain is decomposed by the acid generated from the photoacid generator.

In addition, when the polymer further has an acid-labile group in the side chain, not only a rapid decomposition reaction of the polymer main chain by high-energy rays but also an additional elimination decomposition reaction of the side chain by an acid generated from the photoacid generator occurs simultaneously. Finally, as the molecular weight of the polymer in the high molecular weight state is reduced and the content (or concentration) of polar functional groups that may be dissolved in a developer (e.g., an alkine developer) is increased compared to the initial exposure, the solubility in the developer is further increased, so that even if the exposure dose is lowered, a fine pattern with improved resolution may be efficiently formed, thereby enabling the formation of semiconductor devices having fine patterns with reduced high energy ray photon amounts, reduced environmental pollution, and with improved reliability of the fine pattern formation such that the reliability of the formed semiconductor devices having fine patterns may be improved (due to reduced likelihood of process defects in the fine patterns formed using the resist composition that includes the polymer).

As a result, a resist composition may have improved sensitivity to even a small amount of photons from high energy rays such as EUV and thus may have improved sensitivity and/or resolution and thus may be able to enable improved resolution and reliable formation of fine patterns in manufactured semiconductors, based on the resist composition including a polymer comprising a first repeating unit represented by Formula 1 and a second repeating unit represented by Formula 2.

The polymer has relatively high resistance to oxygen and/or moisture, a relatively high Td (e.g., a Td of 140° C. or higher), and its properties may be changed only by high-energy rays, so that a resist composition with improved storage stability, process stability, etc. may be provided.

The polymer may be prepared by cationic polymerization.

Specifically, the polymer may be produced by a polymer production method that includes polymerizing a mixture using an acid catalyst, wherein the mixture includes a first monomer represented by Formula 1A, and at least one second monomer selected from an aldehyde, an oxirane, a carboxylic anhydride, and a lactone:

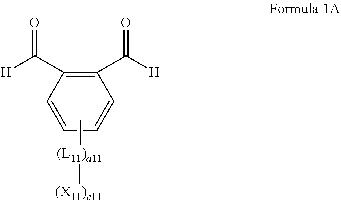

wherein in Formula 1A, the details on L₁₁, a11, X₁₁, and c11 are referred to the description in Formula 1.

For example, in Formula 1A,
L₁₁ may be a single bond; O; S; C(═O); C(═O)O; OC(═O); C(═O)NR₁₁; NR₁₁C(═O); S(═O); S(═O)₂O; OS(═O)₂; or a linear, branched or cyclic C₁-C₃₀ divalent hydrocarbon group optionally including a heteroatom,
a11 may be an integer from 1 to 4,
R₁₁ may be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
X₁₁ may be hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
c11 may be an integer from 1 to 10, and

Formula 1 may optionally include a plurality of X₁₁ based on c11 being greater than 1, and adjacent two of the plurality of X₁₁ may be optionally bound to each other to form a ring.

In some example embodiments, the mixture may further include one or more third monomers selected from vinyl ethers.

In some example embodiments, the polymerizing may additionally utilize a reversible addition-fragmentation chain transfer (RAFT) agent. Here, the RAFT agent may include, for example, dithiobenzoates, trithiocarbonates, or dithiocarbamates, and/or any commercially available product may be used as appropriate.

When additionally utilizing the RAFT agent, the terminal structure of the polymer may be controlled as illustrated in Scheme 1 below:

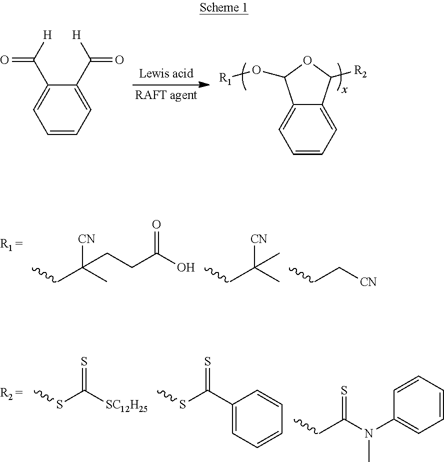

The structure (composition) of the polymer may be confirmed by performing FT-IR analysis, NMR analysis, X-ray fluorescence (XRF) analysis, mass spectrometry, UV analysis, single crystal X-ray structural analysis, powder X-ray diffraction (PXRD) analysis, liquid chromatography (LC) analysis, size exclusion chromatography (SEC) analysis, thermal analysis, etc. The detailed methods are as described in the examples.

### [Resist Composition]

According to some example embodiments of the inventive concepts, a resist composition includes the above-described polymer and a solvent. The resist composition may have properties such as improved developability and/or improved resolution.

The solubility of the resist composition in a developer changes upon exposure to high-energy rays. The resist composition may be a positive resist composition in which an exposed portion of a resist film is dissolved and removed to form a positive resist pattern, or may be a negative resist composition in which an unexposed portion of a resist film is dissolved and removed to form a negative resist pattern. Specifically, the resist composition may be a positive resist composition.

In addition, the resist composition according to some example embodiments may be for a dry developing process that does not use a solvent in the developing process when forming a resist pattern, or for an alkaline developing process that uses an alkaline developer, or for a solvent developing process that uses a developer containing an organic solvent (hereinafter, also referred to as an organic developer) in the developing process. In particular, the resist composition according to some example embodiments may be for an alkaline developing process.

The resist composition may not substantially include a compound having a molecular weight of about 1,000 or more other than the polymer (e.g., may not include any compound having a molecular weight of about 1,000 or more other than the polymer or may not include substantially any compound having a molecular weight of about 1,000 or more other than the polymer), since the properties of the polymer change upon exposure.

The polymer may be used (e.g., included in the resist composition) in an amount of about 0.1 parts to about 80 parts by weight based on 100 parts by weight of the resist composition. Specifically, the polymer may be used in an amount of about 0.5 parts to about 5 parts by weight based on 100 parts by weight of the resist composition. When the above-described range is satisfied, any performance loss (e.g., a performance loss with regard to a resist composition including the polymer used for pattern formation in semiconductor device manufacturing), such as reduced sensitivity and/or formation of foreign particles due to lack of solubility, may be reduced, minimized, or prevented. As a result, a resist composition including the polymer may be configured to enable improved reliability (e.g., reduced likelihood of process defects) of fine patterns formed using a pattern formation process (e.g., based on using the resist composition to form a resist film that is exposed to high-energy rays and developed).

In addition, the polymer used in the resist composition may be used alone, or two or more different types may be used in combination.

As the polymer is as described above, the following describes the solvent and optional components such as a photoacid generator and quencher contained as needed.

### <Solvent>

The solvent included in the resist composition is not particularly limited as long as it can dissolve or disperse optional components such as a polymer, a photoacid generator, and a quencher included as needed.

The solvent may be used alone, or two or more different solvents may be used in combination.

The solvent may be an organic solvent or a mixed solvent of water and an organic solvent.

Examples of organic solvents may include alcohol-based solvents, ether-based solvents, ketone-based solvents, amide-based solvents, ester-based solvents, sulfoxide-based solvents, and hydrocarbon-based solvents.

More specifically, examples of the alcohol-based solvents may include: a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxy butanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonylalcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; a polyalcohol-based solvent such as ethyleneglycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethyleneglycol, dipropyleneglycol, triethylene glycol, and tripropylene glycol; and a polyalcohol-containing ether-based solvent such as ethyleneglycol monomethylether, ethyleneglycol monoethylether, ethyleneglycol monopropylether, ethyleneglycol monobutylether, ethyleneglycol monohexylether, ethyleneglycol monophenylether, ethyleneglycol mono-2-ethylbutylether, diethyleneglycol monomethylether, diethyleneglycol monoethylether, diethyleneglycol monopropylether, diethyleneglycol monobutylether, diethyleneglycol monohexyl ether, diethylene glycol dimethylether, propylene glycol monomethylether, propylene glycol dimethylether, propylene glycol monoethylether, propylene glycol monopropylether, propylene glycol monobutylether, dipropyleneglycol monomethylether, dipropyleneglycol monoethylether, and dipropyleneglycol monopropylether.

Examples of the ether-based solvents may include: a dialkylether-based solvent such as diethylether, dipropylether, and dibutylether; a cyclic ether-based solvent such as tetrahydrofuran and tetrahydropyran; and an aromatic ring-containing ether-based solvent such as diphenylether and anisole.

Examples of the ketone-based solvents may include: a chain-shaped ketone-based solvent such as acetone, methylethylketone, methyl-n-propylketone, methyl-n-butylketone, methyl-n-pentylketone, diethylketone, methylisobutylketone, 2-heptanone, ethyl-n-butylketone, methyl-n-hexylketone, diisobutylketone, and trimethylnonanone; a cyclic ketone-based solvent such as cyclopentanone, cyclohexanone, cycloheptanone, cyclooctanone, and methylcyclohexanone; and 2,4-pentanedione, acetonylacetone, and acetphenone.

Examples of the amide-based solvents may include: a cyclic amide-based solvent such as N,N′-dimethylimidazolidinone and N-methyl-2-pyrrolidone; and a chain-shaped amide-based solvent such as N-methylformamide, N,N-dimethylformamide, N,N-diethylformamide, acetamide, N-methylacetamide, N,N-dimethylacetamide, and N-methylpropyoneamide.

Examples of the ester-based solvents may include: an acetate ester-based solvent such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyalcohol-containing ethercarboxylate-based solvent such as ethyleneglycol monomethylether acetate, ethyleneglycol monoethylether acetate, diethyleneglycol monomethylether acetate, diethyleneglycol monoethylether acetate, diethyleneglycol mono-n-butyl ether acetate, propylene glycol monomethylether acetate (PGMEA), propylene glycol monoethylether acetate, propylene glycol monopropylether acetate, propylene glycol monobutylether acetate, dipropylene glycol monomethylether acetate, and dipropylene glycol monoethylether acetate; a lactone-based solvent such as γ-butyrolactone and 0-valerolactone; a carbonate-based solvent such as dimethyl carbonate, diethyl carbonate, ethylene carbonate, and propylene carbonate; a lactate ester-based solvent such as methyl lactate, ethyl lactate, n-butyl lactate, and n-amyl lactate; and glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-base solvents may include dimethyl sulfoxide and diethyl sulfoxide.

Examples of the hydrocarbon-based solvent may include aliphatic hydrocarbon solvents such as n-pentane, isopentane, n-hexane, isohexane, n-heptane, isoheptane, 2,2,4-trimethyl pentane, n-octane, isooctane, cyclohexane, and methylcyclohexane; and aromatic hydrocarbon solvents such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

Specifically, the organic solvent may be selected from alcohol-based solvents, amide-based solvents, ester-based solvents, sulfoxide-based solvents, and any combination thereof. More specifically, the solvent may be selected from propylene glycol monomethyl ether, propylene glycol monoethyl ether, propylene glycol monomethyl ether acetate, N-methyl-2-pyrrolidone, N,N-dimethylacetamide, ethyl lactate, dimethyl sulfoxide and any combination thereof.

Meanwhile, if an acid-labile group in acetal form is used, a high-boiling alcohol, such as diethylene glycol, propylene glycol, glycerol, 1,4-butanediol, or 1,3-butanediol, may be additionally added to accelerate the deprotection reaction of the acetal.

The solvent may be used in an amount of about 200 parts to about 20,000 parts by weight, specifically, about 2,000 parts to about 10,000 parts by weight, based on 100 parts by weight of the polymer.

### <Photoacid Generator>

The photoacid generator may be any compound capable of generating an acid when exposed to high energy rays, such as UV, DUV, EB, EUV, X-rays, α-rays, γ-rays, etc.

Examples of the photoacid generator may include onium salts, diazomethane derivatives, glyoxime derivatives, β-ketosulfone derivatives, disulfone derivatives, nitrobenzyl sulfonate derivatives, sulfonate derivatives, imid-yl-sulfonate derivatives, oxime sulfonate derivatives, and imino sulfonate derivatives.

The onium salts may include a sulfonium salt, an iodonium salt, and any combination thereof.

In some example embodiments, the onium salt may be represented by Formula 7:

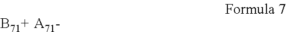

wherein in Formula 7,
B₇₁₊ may be represented by Formula 7A, and A₇₁₋ may be represented by any one of Formulae 7B to 7D, and
B₇₁₊ and A₇₁₋ may optionally be linked via a carbon-carbon covalent bond;

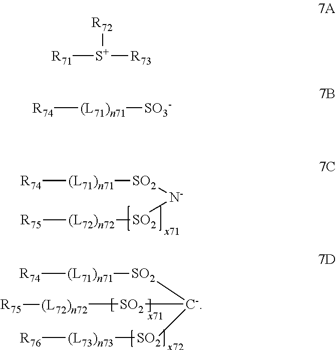

wherein in Formulae 7A to 7D,
L₇₁ to L₇₃ may each independently be a single bond or CRR′,
R and R′ may each independently be hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group or a C₃-C₃₀ cycloalkoxy group,
n71 to n73 may each independently be 1, 2 or 3,
x71 and x72 may each independently be 0 or 1,
R₇₁ to R₇₃ may each independently be a linear, branched or cyclic C₁-C₃₀ monovalent hydrocarbon group optionally including a heteroatom,
adjacent two of R₇₁ to R₇₃ may optionally be bound to each other to form a condensed ring, and
R₇₄ to R₇₆ may each independently be hydrogen; a halogen atom; or a linear, branched or cyclic C₁-C₃₀ monovalent hydrocarbon group optionally including a heteroatom.

For example, in Formula 7, B₇₁₊ may be represented by Formula 7A, and A₇₁₋ may be represented by Formula 7B. Specifically, in formula 7A, R₇₁ to R₇₃ may each be a phenyl group.

Examples of the onium salts may include diphenyliodonium trifluoromethanesulfonate, (p-tert-butoxyphenyl)phenyliodonium trifluoromethanesulfonate, diphenyliodonium p-toluenesulfonate, (p-tert-butoxyphenyl)phenyliodonium p-toluenesulfonate, triphenylsulfonium trifluoromethanesulfonate, (p-tert-butoxyphenyl)diphenylsulfonium trifluoromethanesulfonate, bis(p-tert-butoxyphenyl)phenylsulfonium trifluoromethanesulfonate, tris(p-tert-butoxyphenyl) sulfonium trifluoromethanesulfonate, triphenylsulfonium p-toluenesulfonate, (p-tert-butoxyphenyl)diphenylsulfonium p-toluenesulfonate, bis(p-tert-butoxyphenyl)phenylsulfonium p-toluenesulfonate, tris(p-tert-butoxyphenyl) sulfonium p-toluenesulfonate, triphenylsulfonium nonafluorobutanesulfonate, triphenylsulfonium butanesulfonate, trimethylsulfonium trifluoromethanesulfonate, trimethylsulfonium p-toluenesulfonate, cyclohexylmethyl(2-oxocyclohexyl) sulfonium trifluoromethanesulfonate, cyclohexylmethyl(2-oxocyclohexyl) sulfonium p-toluenesulfonate, dimethylphenylsulfonium trifluoromethanesulfonate, dimethylphenylsulfonium p-toluenesulfonate, dicyclohexylphenylsulfonium trifluoromethanesulfonate, dicyclohexylphenylsulfonium p-toluenesulfonate, bis(4-tert-butylphenyl) iodonium hexafluorophosphate, 4-(phenylthio)phenyl diphenylsulfonium tris(pentafluoroethyl) trifluorophosphate, diphenyl(4-thiophenoxyphenyl) sulfonium hexafluoroantimonate, [4-(4-biphenylylthio)phenyl]-4-biphenylylphenylsulfonium tris(trifluoromethanesulfonyl) methide, triphenylsulfonium tetrakis(fluorophenyl)borate, tris[4-(4-acetylphenyl)thiophenyl]sulfonium tetrakis(fluorophenyl)borate, triphenylsulfonium tetrakis(pentafluorophenyl)borate, and tris[4-(4-acetylphenyl)thiophenyl]sulfonium tetrakis(pentafluorophenyl)borate.

Examples of the diazomethane derivatives may include bis(benzenesulfonyl)diazomethane, bis(p-toluenesulfonyl)diazomethane, bis(xylenesulfonyl)diazomethane, bis(cyclohexylsulfonyl)diazomethane, bis(n-butylsulfonyl)diazomethane, bis(cyclopentylsulfonyl)diazomethane, bis(isobutylsulfonyl)diazomethane, bis(sec-butylsulfonyl)diazomethane, bis(n-propylsulfonyl)diazomethane, bis(isopropylsulfonyl)diazomethane, bis(tert-butylsulfonyl)diazomethane, bis(n-pentylsulfonyl)diazomethane, bis(isopentylsulfonyl)diazomethane, bis(sec-pentylsulfonyl)diazomethane, bis(tert-pentylsulfonyl)diazomethane, 1-cyclohexylsulfonyl-1-(tert-butylsulfonyl)diazomethane, 1-cyclohexylsulfonyl-1-(tert-pentylsulfonyl)diazomethane, and 1-tert-pentylsulfonyl-1-(tert-butylsulfonyl)diazomethane.

Examples of the glyoxime derivatives include bis-o-(p-toluenesulfonyl)-α-dimethylglyoxime, bis-o-(p-toluenesulfonyl)-α-diphenylglyoxime, bis-o-(p-toluenesulfonyl)-α-dicyclohexylglyoxime, bis-o-(p-toluenesulfonyl)-2,3-pentanedioneglyoxime, bis-(p-toluenesulfonyl)-2-methyl-3,4-pentanedioneglyoxime, bis-o-(n-butanesulfonyl)-α-dimethylglyoxime, bis-o-(n-butanesulfonyl)-α-diphenylglyoxime, bis-o-(n-butanesulfonyl)-α-dicyclohexylglyoxime, bis-o-(n-butanesulfonyl)-2,3-pentanedioneglyoxime, bis-o-(n-butanesulfonyl)-2-methyl-3,4-pentanedioneglyoxime, bis-o-(methanesulfonyl)-α-dimethylglyoxime, bis-o-(trifluoromethanesulfonyl)-α-dimethylglyoxime, bis-o-(1,1,1-trifluoroethanesulfonyl)-α-dimethylglyoxime, bis-o-(tert-butanesulfonyl)-α-dimethylglyoxime, bis-o-(perfluorooctanesulfonyl)-α-dimethylglyoxime, bis-o-(cyclohexanesulfonyl)-α-dimethylglyoxime, bis-o-(benzenesulfonyl)-α-dimethylglyoxime, bis-o-(p-fluorobenzenesulfonyl)-α-dimethylglyoxime, bis-o-(p-tert-butylbenzenesulfonyl)-α-dimethylglyoxime, bis-o-(xylenesulfonyl)-α-dimethylglyoxime, and bis-o-(camphorsulfonyl)-α-dimethylglyoxime.

Examples of the β-ketosulfone derivatives may include 2-cyclohexylcarbonyl-2-(p-toluenesulfonyl) propane, and 2-isopropylcarbonyl-2-(p-toluenesulfonyl) propane.

Examples of the disulfone derivatives may include diphenyl disulfone, and dicyclohexyl disulfone, etc.

Examples of the nitrobenzylsulfonate derivatives may include 2,6-dinitrobenzyl p-toluenesulfonate and 2,4-dinitrobenzyl p-toluenesulfonate.

Examples of the sulfonate derivatives may include 1,2,3-tris(methanesulfonyloxy)benzene, 1,2,3-tris(trifluoromethanesulfonyloxy)benzene, and 1,2,3-tris(p-toluenesulfonyloxy)benzene.

Examples of the imide-yl-sulfonate derivatives may include phthalimide-yl-triflate, phthalimide-yl-tosylate, 5-norbornene-2,3-dicarboximide-yl-triflate, 5-norbornene-2,3-dicarboximide-yl-tosylate, 5-norbornene-2,3-dicarboximide-yl-n-butylsulfonate, and n-trifluoromethylsulfonyloxynaphthylimide.

Examples of the oxime sulfonate derivatives may include α-(benzenesulfonium oxyimino)-4-methylphenylacetonitrile and α-(p-tolylsulfonium oxyimino)-p-methoxyphenylacetonitrile.

Examples of the iminosulfonate derivatives may include (5-(4-methylphenyl) sulfonyloxyimino-5H-thiophene-2-ylidene)-(2-methylphenyl) acetonitrile and (5-(4-(4-methylphenylsulfonyloxy)phenylsulfonyloxyimino)-5H-thiophene-2-ylidene)-(2-methylphenyl)-acetonitrile.

The photoacid generator may be included (e.g., included in the resist composition) in an amount of about 0.01 parts to about 40 parts by weight, about 0.1 parts to about 40 parts by weight, or about 0.1 parts to about 20 parts by weight based on 100 parts by weight of the polymer. When the above range is satisfied, appropriate resolution may be achieved and issues related to foreign particles after development or during stripping may be reduced. As a result, a resist composition including the photoacid generator may be configured to enable improved reliability (e.g., reduced likelihood of process defects) of fine patterns formed using a pattern formation process (e.g., based on using the resist composition to form a resist film that is exposed to high-energy rays and developed).

The photoacid generator may be used alone, or two or more different types may be used in combination.

### <Quencher>

The resist composition may further include a quencher.

The quencher may be a salt which generates an acid having a weaker acidity than the acid generated from the photoacid generator.

The quencher may include ammonium salts, sulfonium salts, iodonium salts, and any combination thereof.

In some example embodiments, the quencher may be represented by Formula 8:

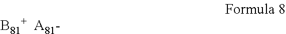

wherein in Formula 8,
B₈₁₊ may be represented by any one of Formulae 8A to 8C, and A₈₁₋ may be represented by any one of Formulae 8D to 8F,
B₈₁₊ and A₈₁₋ may optionally be linked via a carbon-carbon covalent bond;

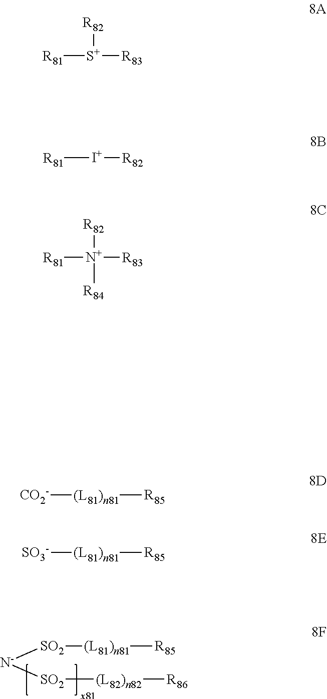

wherein in Formulae 8A to 8F,
L₈₁ and L₈₂ may each independently be a single bond or CRR′,
R and R′ may each independently be hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group or a C₃-C₃₀ cycloalkoxy group,
n81 and n82 may each independently be 1, 2 or 3,
x81 may be 0 or 1,
R₈₁ to R₈₄ may each independently be a linear, branched or cyclic C₁-C₃₀ monovalent hydrocarbon group optionally including a heteroatom,
adjacent two of R₈₁ to R₈₄ may be optionally bound to each other to form a condensed ring, and
R₈₅ and R₈₆ may each independently be hydrogen; a halogen atom; or a linear, branched or cyclic C₁-C₃₀ monovalent hydrocarbon group optionally including a heteroatom.

The quencher may be included (e.g., included in the resist composition) in an amount of about 0 part to about 10 parts by weight, about 0.05 parts to about 5 parts by weight, or about 0.1 parts to about 3 parts by weight, based on 100 parts by weight of the polymer. When the above range is satisfied, appropriate resolution may be achieved and issues related to foreign particles after development or during stripping may be reduced. As a result, a resist composition including the quencher may be configured to enable improved reliability (e.g., reduced likelihood of process defects) of fine patterns formed using a pattern formation process (e.g., based on using the resist composition to form a resist film that is exposed to high-energy rays and developed).

The quencher may be used alone, or two or more different types may be used in combination (e.g., two or more different types of quenchers may be mixed and used).

### <Optional Component>

The resist composition may further include a surfactant, a cross-linking agent, a leveling agent, a colorant, or any combination thereof, as needed.

The resist composition may further include a surfactant to improve coatability, developability, and the like. Examples of the surfactant may include a nonionic surfactant such as polyoxyethylene lauryl ether, polyoxyethylene stearyl ether, polyoxyethyleneoleyl ether, polyoxyethylene n-octylphenyl ether, polyoxyethylene n-nonylphenyl ether, polyethyleneglycol dilaurate, and polyethyleneglycol distearate. Any commercially available product or a synthetic product may be used as the surfactant. Examples of the commercially available product may include KP341 (manufactured by Shin-Etsu Chemical Co., Ltd.), Polyflow No. 75 and Polyflow No. 95 (manufactured by Kyoeisha Chemical Co., Ltd.), Eftop EF301, Eftop EF303, and Eftop EF352 (manufactured by Mitsubishi Materials Electronic Chemicals Co., Ltd.), MEGAFACE® F171, MEGAFACE F173, R40, R41, and R43 (manufactured by DIC Corporation), Fluorad® FC430, Fluorad FC431 (manufactured by 3M Co., Ltd.), AsahiGuard AG710 (manufactured by AGC Co., Ltd.), and Surflon® S-382, Surflon SC-101, Surflon SC-102, Surflon SC-103, Surflon SC-104, Surflon SC-105, and Surflon SC-106 (manufactured by AGC Seimi Chemical Co., Ltd).

The surfactant may be included (e.g., in the resist composition) in an amount of about 0 part to about 20 parts by weight based on 100 parts by weight of the polymer.

The surfactant may be used alone, or two or more different types may be used in combination.

The method of producing the resist composition is not particularly limited, and for example, any method of mixing an amine compound, a polymer, a photoacid generator, and optional components added as needed in an organic solvent may be used. Temperature or time in the mixing is not particularly limited. If necessary, filtration may be performed after the mixing.

### [Pattern Formation Method]

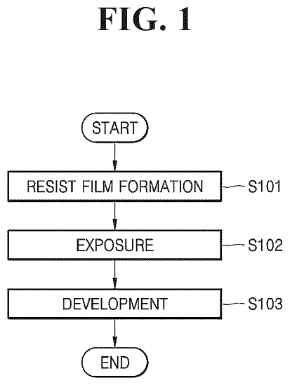

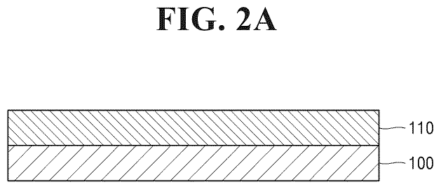

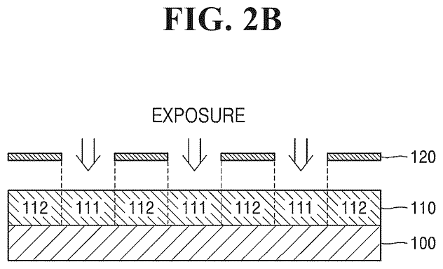

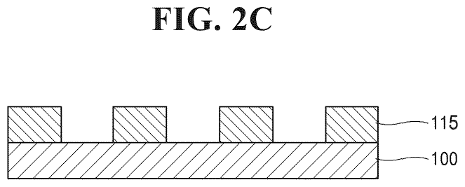

Hereinafter, a method of forming a pattern according to some example embodiments will be described in more detail with reference to FIG. 1 and FIGS. 2A to 2C. FIG. 1 is a flowchart illustrating a method of forming a pattern according to some example embodiments, and FIGS. 2A to 2C are cross-sectional side views illustrating a method of forming a pattern according to some example embodiments. Hereinafter, a method of forming a pattern by using a positive resist composition will be described by way of an example, but example embodiments are not limited thereto.

Referring to FIG. 1, a method of forming a pattern may include applying a resist composition to form a resist film (S101), exposing at least a portion of the resist film to high-energy rays (S102), and developing the exposed resist film using a developer (S103). These operations may be omitted or may be performed in a different order, if necessary.

First, a substrate 100 is prepared. The substrate 100 may be a semiconductor substrate such as a silicon substrate and a germanium substrate, or may be formed of glass, quartz, ceramic, copper, or the like. In some example embodiments, the substrate 100 may include Groups III to V compounds, such as GaP, GaAs, and GaSb.

As shown at FIGS. 1 and 2A, a resist film 110 may be formed on the substrate 100 by applying the resist composition thereto to a desired thickness using a coating method. If necessary, a post application bake (PAB) may be performed to remove the organic solvent remaining in the resist film 110. The resist film 110 may include a resist composition according to any of the example embodiments and may include the polymer according to any of the example embodiments.

As the coating method, spin coating, dipping, roller coating, or other common coating methods may be used. Among them, spin coating may be used in particular, and the resist film 110 having a desired thickness may be formed by adjusting viscosity, concentration, and/or spin speed of the resist composition. Specifically, the resist film 110 may have a thickness of about 10 nm to about 300 nm. More specifically, the resist film 110 may have a thickness of about 30 nm to about 200 nm.

The lower limit of a PAB temperature may be 60° C. or higher, specifically, 80° C. or higher. In addition, the upper limit of the PAB temperature may be 150° C. or less, specifically, 140° C. or lower. The lower limit of a PAB time may be 5 seconds or more, specifically, 10 seconds or more. The upper limit of the PAB time may be 600 seconds or less, specifically, 300 seconds or less.

Before applying the resist composition on the substrate 100, a film to be etched (not shown) may be also formed on the substrate 100. The film to be etched may refer to a layer onto which an image is transferred from a resist pattern and converted into a pattern. In some example embodiments, the film to be etched may be formed to include, for example, an insulating material such as a silicon oxide, a silicon nitride, and a silicon oxynitride. In some example embodiments, the film to be etched may be formed to include a conductive material such as a metal, a metal nitride, a metal silicide, and a metal silicide nitride film. In some example embodiments, the film to be etched may be formed to include a semiconductor material such as polysilicon.

In some example embodiments, an anti-reflection film may further be formed on the substrate 100 to increase or maximize efficiency of the resist. The anti-reflection film may be an organic or inorganic anti-reflection film.

In some example embodiments, a protective film may further be formed on the resist film 110 to reduce effects of alkaline impurities included during a process. In addition, in the case of performing immersion lithography, a protective film for immersion lithography may be formed on the resist film 110 to avoid direct contact between an immersion medium and the resist film 110.

Subsequently, as shown at FIGS. 1 and 2B, at least a portion of the resist film 110 may be exposed to high-energy rays. For example, high-energy rays having passed through a mask 120 may reach at least one portion of the resist film 110. Therefore, the resist film 110 may have an exposed portion 111 and an unexposed portion 112.

In some example embodiments, the exposure may be performed by irradiating high-energy rays through a mask with a certain pattern by using a liquid such as water as a medium. Examples of the high-energy rays may include electromagnetic waves such as ultraviolet rays, deep ultraviolet (DUV) rays, extreme ultraviolet (EUV) rays (wavelength of 13.5 nm), X-rays, and y-rays; and charged particle beams such as electron beams (Ebs) and α particle beams. Irradiation of these high-energy rays may be collectively referred to as “exposure.”

Various light sources may be used for the exposure, for example, a light source emitting laser beams in the UV range, such as a KrF excimer laser (wavelength of 248 nm), an ArF excimer laser (wavelength of 193 nm), and an F₂ excimer laser (wavelength of 157 nm), a light source emitting harmonic laser beams in the far ultraviolet or vacuum ultraviolet range by converting wavelengths of laser beams received from a solid laser light source (YAG or semiconductor laser), and a light source emitting Ebs or EUVs may be used. During exposure, the exposure may be usually performed through a mask corresponding to a desired pattern, but when exposure light is an EB, the exposure may be performed through direct writing without using a mask.

The integrated dose of high-energy rays, for example, when using extreme ultraviolet rays as high-energy rays, may be 2000 mJ/cm² or less, specifically 500 mJ/cm² or less. In addition, when Ebs are used as the high energy rays, the integral dose may be 5,000 μC/cm² or less, or 1,000 μC/cm² or less.

Additionally, a post exposure bake (PEB) may be performed. The lower limit of the temperature of PEB may be 50° C. or more, specifically 80° C. or more. The upper limit of the PEB temperature may be 180° C. or lower, specifically 130° C. or lower. The lower limit of the time of the PEB time may be 5 seconds or more, specifically 10 seconds or more. The upper limit of the time of the PEB may be 600 seconds or less, specifically 300 seconds or less.

Next, as shown at FIGS. 1 and 2C, the exposed resist film 110 may be developed by using a developer. The exposed portion 111 may be washed away by the developer, and the unexposed portion 112 may remain unwashed away by the developer to define a resist pattern 115.

In some example embodiments, for example as shown at FIGS. 1 and 2C, a resist thin film formed from the resist composition may be subjected to a dry development process for forming a pattern during the PEB process without developer treatment. In this case, the exposed portion 111 is removed and the unexposed portion 112 remains.

In some example embodiments, for example as shown at FIGS. 1 and 2C, a wet development process using a developer may be applied to develop the exposed resist film 110. In this case, the exposed portion 111 may be washed away by the developer, while the unexposed portion 112 remain without being washed away by the developer.

Examples of the developer may include an alkaline developer, and a developer including an organic solvent (hereinafter also referred to as “organic developer”). Examples of a development method may include a dipping method, a puddle method, a spray method, and a dynamic injection method. The developing temperature may be, for example, about 5° C. or more and about 60° C. or less, and a developing time may be, for example, about 5 seconds or more and about 300 seconds or less.

Examples of the alkaline developer may include an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

The lower limit of an amount of the alkaline compound included in the alkaline developer may be 0.1 wt % or more, specifically 0.5 wt % or more, and more specifically 1 wt % or more. Additionally, the upper limit of the amount of the alkaline compound included in the alkaline developer may be 20 wt % or less, specifically 10 wt % or less, and more specifically 5 wt % or less.

After development, the resist pattern 115 may be washed with ultrapure water, and then any water remaining on the substrate and pattern may be removed.

Examples of the organic solvent included in the organic developer may include the same organic solvents as those exemplified in the part of <Solvent> of [Resist composition].

The lower limit of the organic solvent content in the organic developer may be 80 wt % or more, specifically 90 wt % or more, more specifically 95 wt % or more, and especially 99 wt % or more.

The organic developer may also include surfactants. Additionally, the organic developer may include trace amounts of moisture. Additionally, development may be stopped by substituting a different type of solvent from the organic developer during development.

The resist pattern 115 after development may be further cleaned. Cleaning solutions such as ultrapure water and rinse solution may be used. There are no particular restrictions on the rinse solution as long as it does not dissolve the resist pattern 115, and common solutions containing organic solvents may be used. For example, the rinse solution may be an alcohol-based solvent or an ester-based solvent. After cleaning, any remaining rinse solution on the substrate and the resist pattern may be removed. When ultrapure water is used, any remaining water on the substrate and pattern may be removed.

Additionally, the developer may be used alone or in combination of two or more types.

As described above, after forming the resist pattern, a patterned wiring substrate may be obtained by etching. The etching method may be carried out using well-known methods such as dry etching with plasma gas, and wet etching with alkaline solutions, copper (II) chloride solutions, or iron (III) chloride solutions.

After forming the resist pattern, plating may also be performed. The plating method is not particularly limited, but examples include copper plating, solder plating, nickel plating, and gold plating.

The remaining resist pattern after etching may be stripped using an organic solvent. Examples of such organic solvents may include, but are not limited to, propylene glycol monomethyl ether acetate (PGMEA), propylene glycol monomethyl ether (PGME), and ethyl lactate (EL). The stripping method is not particularly limited and may include, for example, immersion methods and spray methods. Additionally, the wiring substrate with the resist pattern formed may be a multilayer wiring substrate and may have small-diameter through holes.

In some example embodiments, the wiring substrate is formed by depositing metal in a vacuum after forming the resist pattern, and then dissolving the resist pattern in a solution, a method known as the lift-off method.

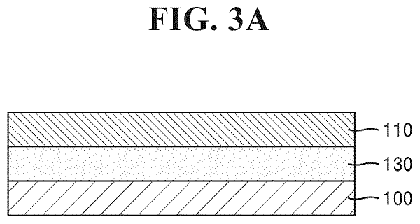

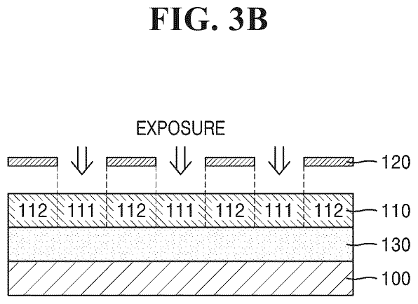

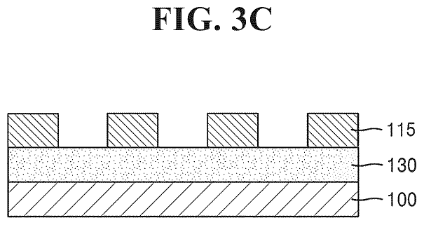

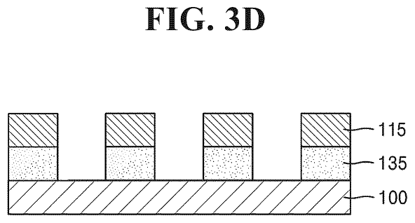

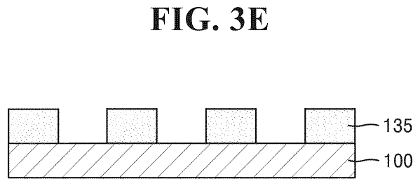

FIGS. 3A, 3B, 3C, 3D, and 3E are cross-sectional side views showing a method of forming a patterning structure according to some example embodiments.

As shown in FIG. 3A, a material layer 130 may be formed on the substrate 100 at S101 in FIG. 1 before forming the resist film 110 on the substrate 100. At S101, the resist film 110 (which may include a resist composition according to any of the example embodiments and thus may include the polymer according to any of the example embodiments) be formed on top of the material layer 130. The material layer 130 may include an insulating material (e.g., silicon oxide, silicon nitride), a semiconductor material (e.g., silicon), or a metal (e.g., copper). In some example embodiments, the material layer 130 may have a multi-layer structure. The material of the material layer 130 may be different from the material of the substrate 100.

As shown in FIG. 3B, the resist film 110 may undergo a prebake process before exposure and then be exposed to high-energy rays through the mask 120, and subsequently the resist film 110 may include an exposed portion 111 and an unexposed portion 112.

As shown in FIG. 3C, the exposed resist film 110 may be developed using a developer. The exposed portion 111 may be washed away by the developer, while the unexposed portion 112 remain without being washed away by the developer.

As shown in FIG. 3D, the resist pattern 115 may serve as a mask for etching the exposed portions of the material layer 130 to form the material pattern 135 on the substrate 100.

As shown in FIG. 3E, the resist pattern 115 may be removed.

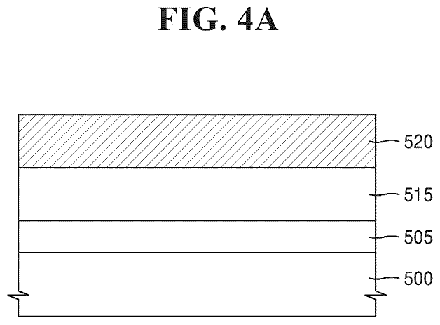

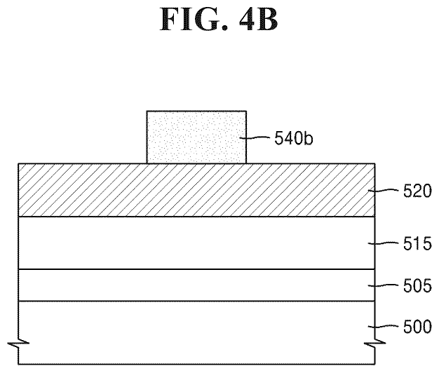

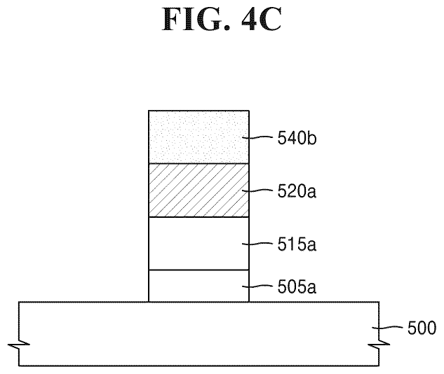

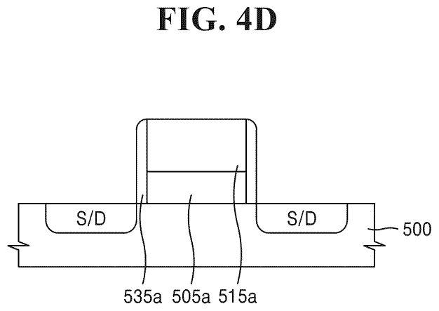

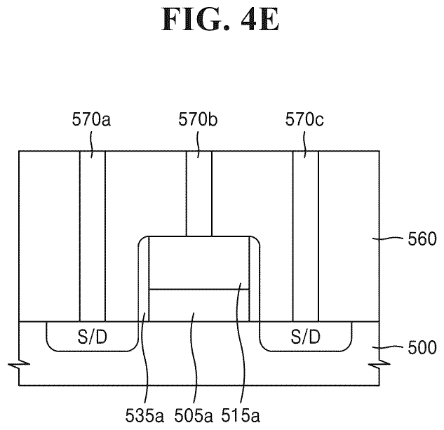

FIGS. 4A, 4B, 4C, 4D, and 4E are cross-sectional side views showing a method of forming a semiconductor device according to some example embodiments.

As shown in FIG. 4A, a gate dielectric 505 (e. g., silicon oxide) may be formed on the substrate 500. The substrate 500 may be a semiconductor substrate such as a silicon substrate. A gate layer 515 (e.g., doped polysilicon) may be formed on gate dielectric 505. A hardmask layer 520 may be formed on the gate layer 515.

As shown in FIG. 4B, a resist pattern 540b may be formed on the hardmask layer 520. The resist pattern 540b may be formed using a resist composition according to any of the example embodiments and thus may include the polymer according to any of the example embodiments. The resist composition may include an organic solvent.

As shown in FIG. 4C, the gate layer 515 and the gate dielectric 505 may be etched to form a hardmask pattern 520a, a gate electrode pattern 515a, and a gate dielectric pattern 505a.

As shown in FIG. 4D, a spacer layer may be formed on the gate electrode pattern 515a and the gate dielectric pattern 505a. The spacer layer can be formed using a deposition process (e.g., CVD). The spacer layer may be etched to form spacers 535a (e.g., silicon nitride) on the sidewalls of the gate electrode pattern 515a and the gate dielectric pattern 505a. After forming the spacers 535a, ions may be implanted into the substrate 500 to form source/drain impurity regions (S/D).

As shown in FIG. 4E, an interlayer insulating film 560 (e.g., an oxide) may be formed on the substrate 500, covering the gate electrode pattern 515a, gate dielectric pattern 505a, and spacers 535a. Subsequently, the interlayer insulating film 560 may have electrical contacts 570a, 570b, and 570c formed to connect with the gate electrode pattern 515a and the S/D regions. The electrical contacts 570a, 570b, and 570c may be formed of a conductive material (e.g., metal). Although not shown, a barrier layer may be formed between the sidewalls of the interlayer insulating film 560 and the electrical contacts 570a, 570b, and 570c.

FIGS. 4A to 4E show examples of forming transistors, but the inventive concepts are not limited thereto.

The resist composition according to some example embodiments may be used in the patterning process to form other types of semiconductor devices.

While the inventive concepts will be described in more detail using the following examples and comparative examples, the technical scope of the inventive concepts are not limited to these examples.

### EXAMPLES

### Comparative Synthesis Example 1: Synthesis of Polymer X-1

In a flask, 0.4725 g (3.52 mmol, 50 eq) of phthalaldehyde was dissolved in 4.2525 g of anhydrous dichloromethane and stirred at −78° C. for 3 minutes. Afterwards, 0.0100 g (0.071 mmol, 1 eq) of boron trifluoride diethyl etherate was diluted in 0.4729 g of anhydrous dichloromethane, stirred at a low temperature for 3 minutes, rapidly added to the reaction mixture, sealed, and stirred at −78° C. for 1 hour. To terminate the reaction, 0.5573 g (7.05 mmol, 100 eq) of pyridine was added to the reaction mixture and stirred for an additional 30 minutes. The reaction mixture was added dropwise to an excess of methyl alcohol, and the formed white solid product was filtered under reduced pressure through a Buchner funnel. The obtained solid product was dissolved in a small amount of tetrahydrofuran, and then reprecipitated by adding one drop at a time to an excess of methyl alcohol. The formed solid precipitate was filtered under reduced pressure using a Buchner funnel. The finally obtained solid product was stored in a vacuum oven at 30° C. for about one day to dry.

### Synthesis Example 1: Synthesis of Polymer P-1

0.6639 g (4.70 mmol, 15 eq) of phthalaldehyde and 0.4615 g (4.70 mmol, 15 eq) of 1,2-epoxycyclohexane were dissolved in 4.5018 g of anhydrous dichloromethane and stirred at −78° C. for 3 minutes. Afterwards, 0.0900 g (0.31 mmol, 1 eq) of bis(trifluoromethanesulfonyl)imide was diluted in 1.1254 g of anhydrous dichloromethane, stirred at a low temperature for 3 minutes, rapidly added to the reaction mixture, sealed, and stirred at −78° C. for 2 hours. To terminate the reaction, 1.4878 g (18.81 mmol, 60 eq) of pyridine was added to the solution and stirred for an additional 30 minutes. The reaction mixture was added dropwise to an excess of methyl alcohol, and the formed white solid product was filtered under reduced pressure through a Buchner funnel. The obtained solid product was dissolved in a small amount of tetrahydrofuran, and then reprecipitated by adding one drop at a time to an excess of methyl alcohol. The formed solid precipitate was filtered under reduced pressure using a Buchner funnel. The finally obtained solid product was stored in a vacuum oven at 30° C. for about one day to dry.

### Synthesis Example 2: Synthesis of Polymer P-2

0.7461 g (5.28 mmol, 15 eq) of phthalaldehyde and 0.4615 g (4.70 mmol, 15 eq) of 1,2-epoxycyclohexane were dissolved in 5.0589 g of anhydrous dichloromethane, and stirred at −78° C. for 3 minutes. Afterwards, 0.0500 g (0.35 mmol, 1 eq) of boron trifluoride diethyl etherate was diluted in 1.2647 g of anhydrous dichloromethane, stirred at a low temperature for 3 minutes, rapidly added to the reaction mixture, sealed, and stirred at −78° C. for 2 hours. To terminate the reaction, 0.7130 g (7.05 mmol, 20 eq) of triethylamine was added to the solution and stirred for an additional 30 minutes. The reaction mixture was added dropwise to an excess of methyl alcohol, and the formed white solid product was filtered under reduced pressure through a Buchner funnel. The obtained solid product was dissolved in a small amount of tetrahydrofuran, and then reprecipitated by adding one drop at a time to an excess of methyl alcohol. The formed solid precipitate was filtered under reduced pressure using a Buchner funnel. The finally obtained solid product was stored in a vacuum oven at 30° C. for about one day to dry.

### Synthesis Example 3: Synthesis of Polymer P-3

0.4029 g (2.85 mmol, 15 eq) of phthalaldehyde, 0.2400 g (2.85 mmol, 15 eq) of 3,4-dihydro-2H-pyran and 0.6342 g (2.85 mmol, 15 eq) of tert-butyl(4-formylphenyl) carbonate were dissolved in 3.0708 g of anhydrous dichloromethane and stirred at −78° C. for 3 minutes. Afterwards, 0.0270 g (0.19 mmol, 1 eq) of boron trifluoride diethyl etherate was diluted in 0.7677 g of anhydrous dichloromethane, stirred at low temperature for 3 minutes, then rapidly added to the above solution, sealed, and stirred at −78° C. for 2 hours. To terminate the reaction, 0.9028 g (11.41 mmol, 60 eq) of pyridine was added to the solution and stirred for an additional 30 minutes. The reaction mixture was added dropwise to an excess of methyl alcohol, and the formed white solid product was filtered under reduced pressure through a Buchner funnel. The obtained solid product was dissolved in a small amount of tetrahydrofuran, and then reprecipitated by adding one drop at a time to an excess of methyl alcohol. The formed solid precipitate was filtered under reduced pressure using a Buchner funnel. The finally obtained solid product was stored in a vacuum oven at 30° C. for about one day to dry.

### Synthesis Example 4: Synthesis of Polymer P-4

0.7030 g (3.13 mmol, 15 eq) of phthalaldehyde and 0.3077 g (3.13 mmol, 15 eq) of 1,2-epoxycyclohexane were dissolved in 4.0427 g of anhydrous dichloromethane, and stirred at −78° C. for 3 minutes. Afterwards, 0.0600 g (0.21 mmol, 1 eq) of bis(trifluoromethanesulfonyl)imide was diluted in 1.0106 g of anhydrous dichloromethane, stirred at low temperature for 3 minutes, then rapidly added to the solution, sealed, and stirred at −78° C. for 1 hour. To terminate the reaction, 0.9919 g (12.54 mmol, 60 eq) of pyridine was added to the solution and stirred for an additional 30 minutes. The reaction mixture was added dropwise to an excess of methyl alcohol, and the formed white solid product was filtered under reduced pressure through a Buchner funnel. The obtained solid product was dissolved in a small amount of tetrahydrofuran, and then reprecipitated by adding one drop at a time to an excess of methyl alcohol. The formed solid precipitate was filtered under reduced pressure using a Buchner funnel. The finally obtained solid product was stored in a vacuum oven at 30° C. for about one day to dry.

### Synthesis Example 5: Synthesis of Polymer P-5

0.4098 g (2.90 mmol, 15 eq) of phthalaldehyde, 0.2466 g (2.90 mmol, 15 eq) of 3,4-dihydro-2H-pyran, and 0.5987 g (2.90 mmol, 15 eq) of 4-(2-tetrahydropyranyloxy)benzaldehyde were dissolved in 3.0122 g of anhydrous dichloromethane, and then the mixture was stirred at −78° C. for 3 minutes. Afterwards, 0.0550 g (0.19 mmol, 1 eq) of Bis(trifluoromethanesulfonyl) imide was diluted in 0.7531 g of anhydrous dichloromethane, stirred at low temperature for 3 minutes, then rapidly added to the solution, sealed, and stirred at −78° C. for 1 hour. To terminate the reaction, 0.9184 g (11.61 mmol, 60 eq) of pyridine was added to the solution and stirred for an additional 30 minutes. The reaction mixture was added dropwise to an excess of methyl alcohol, and the formed white solid product was filtered under reduced pressure through a Buchner funnel. The obtained solid product was dissolved in a small amount of tetrahydrofuran, and then reprecipitated by adding one drop at a time to an excess of methyl alcohol. The formed solid precipitate was filtered under reduced pressure using a Buchner funnel. The finally obtained solid product was stored in a vacuum oven at 30° C. for about one day to dry.

### Synthesis Example 6: Synthesis of Polymer P-6

0.5969 g (4.45 mmol, 15 eq) of phthalaldehyde and 0.5079 g (4.23 mmol, 15 eq) of styrene oxide were dissolved in 4.4191 g of anhydrous dichloromethane, and stirred at −78° C. for 3 minutes. Afterwards, 0.0400 g (0.28 mmol, 1 eq) of boron trifluoride diethyl etherate was diluted in 1.1048 g of anhydrous dichloromethane, stirred at low temperature for 3 minutes, then rapidly added to the above solution, sealed, and stirred at −78° C. for 2 hours. To terminate the reaction, 1.3376 g (16.91 mmol, 60 eq) of pyridine was added to the solution and stirred for an additional 30 minutes. The reaction mixture was added dropwise to an excess of methyl alcohol, and the formed white solid product was filtered under reduced pressure through a Buchner funnel. The obtained solid product was dissolved in a small amount of tetrahydrofuran, and then reprecipitated by adding one drop at a time to an excess of methyl alcohol. The formed solid precipitate was filtered under reduced pressure using a Buchner funnel. The finally obtained solid product was stored in a vacuum oven at 30° C. for about one day to dry.

### Synthesis Example 7: Synthesis of Polymer P-7

0.7079 g (5.01 mmol, 15 eq) of phthalaldehyde and 1.1043 g (5.01 mmol, 15 eq) of (4-(2-tetrahydropyranyloxy)styreneoxide) were dissolved in 4.3493 g of anhydrous dichloromethane, and stirred at −78° C. for 3 minutes. Afterwards, 0.0950 g (0.33 mmol, 1 eq) of Bis(trifluoromethanesulfonyl) imide was diluted in 1.0873 g of anhydrous dichloromethane, stirred at low temperature for 3 minutes, then rapidly added to the solution, sealed, and stirred at −78° C. for 1 hour. To terminate the reaction, 1.5863 g (20.05 mmol, 60 eq) of pyridine was added to the solution and stirred for an additional 30 minutes. The reaction mixture was added dropwise to an excess of methyl alcohol, and the formed white solid product was filtered under reduced pressure through a Buchner funnel. The obtained solid product was dissolved in a small amount of tetrahydrofuran, and then reprecipitated by adding one drop at a time to an excess of methyl alcohol. The formed solid precipitate was filtered under reduced pressure using a Buchner funnel. The finally obtained solid product was stored in a vacuum oven at 30° C. for about one day to dry.

### Synthesis Example 8: Synthesis of Polymer P-8

0.3688 g (2.61 mmol, 15 eq) of phthalaldehyde, 0.2784 g (2.61 mmol, 15 eq) of 2-chloroethyl vinyl ether, and 0.5388 g (2.61 mmol, 15 eq) of 4-(2-tetrahydropyranyloxy)benzaldehyde were dissolved in 2.8464 g of anhydrous dichloromethane, and the mixture was stirred at −78° C. for 3 minutes. Afterwards, 0.0500 g (0.17 mmol, 1 eq) of bis(trifluoromethanesulfonyl)imide was diluted in 0.7116 g of anhydrous dichloromethane, stirred at low temperature for 3 minutes, then rapidly added to the solution, sealed, and stirred at −78° C. for 1 hour. To terminate the reaction, 0.82666 g (10.45 mmol, 60 eq) of pyridine was added to the solution and stirred for an additional 30 minutes. The reaction mixture was added dropwise to an excess of methyl alcohol, and the formed white solid product was filtered under reduced pressure through a Buchner funnel. The obtained solid product was dissolved in a small amount of tetrahydrofuran, and then reprecipitated by adding one drop at a time to an excess of methyl alcohol. The formed solid precipitate was filtered under reduced pressure using a Buchner funnel. The finally obtained solid product was stored in a vacuum oven at 30° C. for about one day to dry.

A number average molecular weight and PDI of the polymers obtained in Synthesis Examples 1 to 8 and Comparative Synthesis Example 1 are listed in Table 1 below.

TABLE 1

| | | | Number | |
|---|---|---|---|---|
| | | | average | |
| | | | molecular | |
| | | | weight | |
| Polymer | Monomer | Molar ratio | (Mn) | PDI |
| P-1 | F_{PHA}/F_{CHO} | 1/1 | 6.26k | 1.97 |
| P-2 | F_{PHA}/F_{CHO} | 1/7 | 2.86k | 3.12 |
| P-3 | F_{PHA}/F_{DHP}/F_{tBFPC} | 1/1/1 | 7.5k | 2.0 |
| P-4 | F_{BPHA}/F_{CHO} | 1/5.58 | 3.01k | 1.80 |
| P-5 | F_{PHA}/F_{OTHPB}/F_{DHP} | 1/1.58/1.38 | 1.55k | 1.70 |
| P-6 | F_{PHA}/F_{SO} | 1/0.11 | 4.75k | 2.55 |
| P-7 | F_{PHA}/F_{THPO} | 1/0.59 | 1.03k | 1.40 |
| P-8 | F_{PHA}/F_{OTHPB}/F_{CEVE} | 1/2.4/4.3 | 1.47k | 1.56 |
| X-1 | F_{PHA} | 1 | 91.27k | 1.61 |

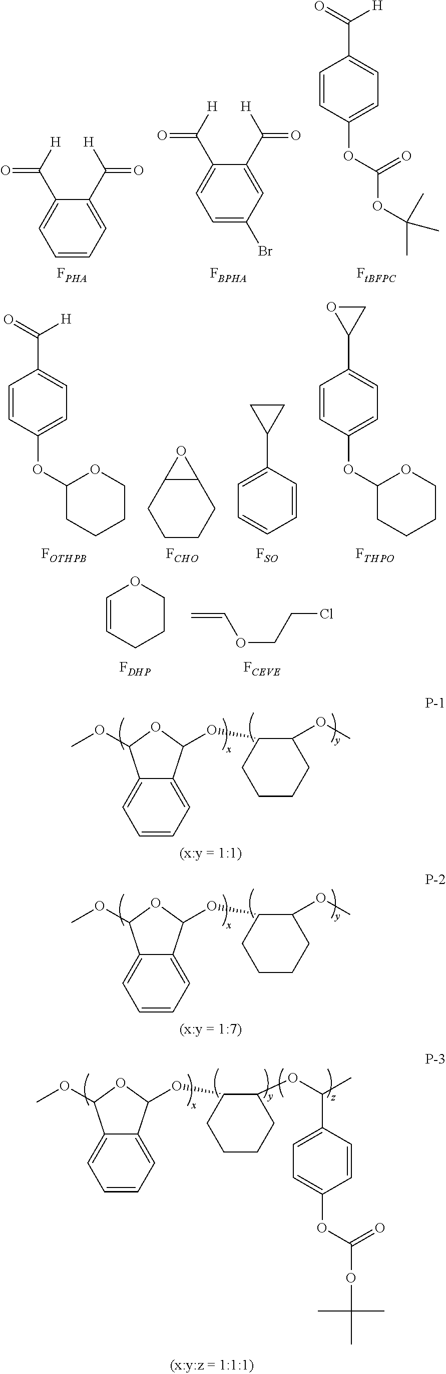

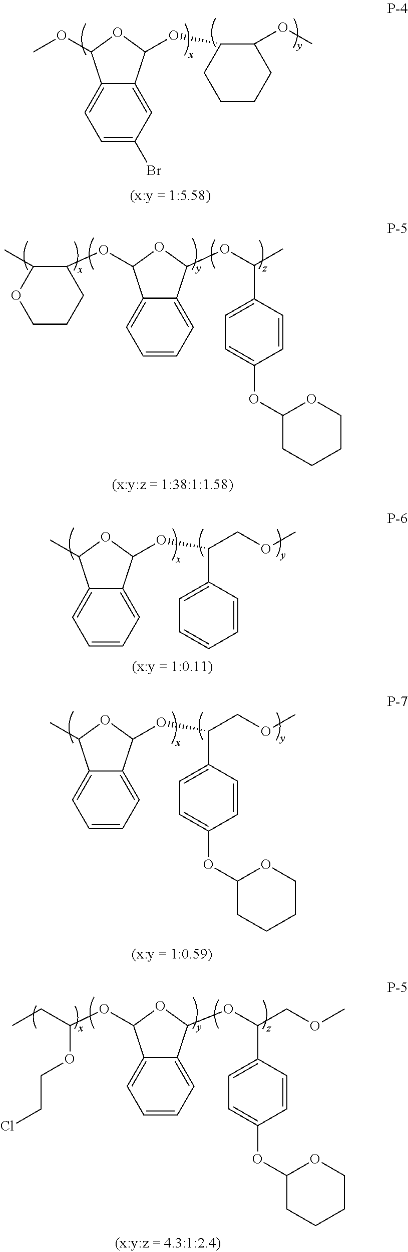

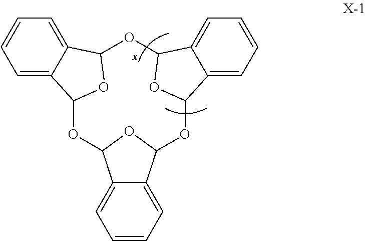

### Evaluation Example 1: Thermal Stability Evaluation

For the polymers obtained in Synthesis Examples 1 to 8 and Comparative Synthesis Example 1, thermal analysis was performed using Thermo Gravimetric Analysis (TGA) (N₂ atmosphere, temperature range: from room temperature to 600° C. (10° C./min), Pan Type: Pt Pan in disposable Al Pan), and the results are shown in Table 2. Here, the temperature at which the mass of the sample becomes 95% of the initial mass is denoted as T_{d}.

TABLE 2

| Polymer | Monomer | Molar ratio | Td (° C. ) |
|---|---|---|---|
| P-1 | F_{PHA}/F_{CHO} | 1/1 | 145.7 |
| P-2 | F_{PHA}/F_{CHO} | 1/7 | 285.2 |
| P-3 | F_{PHA}/F_{DHP}/F_{tBFPC} | 1/1/1 | 185.1 |
| P-4 | F_{BPHA}/F_{CHO} | 1/5.58 | 162.3 |
| P-5 | F_{PHA}/F_{OTHPB}/F_{DHP} | 1/1.58/1.38 | 180.6 |
| P-6 | F_{PHA}/F_{SO} | 1/0.11 | 141.5 |
| P-7 | F_{PHA}/F_{THPO} | 1/0.59 | 158.0 |
| P-8 | F_{PHA}/F_{OTHPB}/F_{CEVE} | 1/2.4/4.3 | 170.5 |
| X-1 | F_{PHA} | 1 | 130.7 |

Referring to Table 2 above, it was confirmed that polymers P-1 to P-8 have relatively improved Td values in comparison to polymer X-1, and from this it can be seen that polymers P-1 to P-8 have improved thermal stability than polymer X-1.

### Evaluation Example 2: Thin Film Phenomena Evaluation

The polymers synthesized in Comparative Synthesis Example 1 and Synthesis Examples 1 to 8 were each dissolved in PGMEA casting solvent to a concentration of 10 wt %/vol %, and then PAG was added thereto to achieve a concentration of 2.5 or 3.0 wt % relative to the polymer. The casting solution was spin-coated on a silicon wafer cleaned with acetone, isopropyl alcohol, and toluene at 5000 rpm for 50 seconds, and the coated wafer was then dried (PAB) at either 60° C. or 110° C. for 90 seconds to produce a film. Next, the films were exposed to I-line light with a wavelength of 365 nm at doses ranging from 0 to 32 mJ/cm². Post-exposure bake (PEB) was performed for 20 seconds or 60 seconds at either 60° C. or 110° C. Various developers, including propylene glycol methyl ether, n-butyl acetate, 2.38 wt % TMAH aqueous solution, ethyl acetate, and isopropyl alcohol, were used to develop the exposed areas by immersing the wafers at 25° C. for 5 to 30 seconds. After development and drying, the resulting pattern images were observed using an optical microscope (Olympus, BX53M), and the pattern formation capability is shown in Table 3.

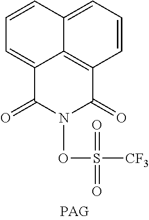 [SMILES: O=C1c2cccc3cccc(c23)C(=O)N1OS(=O)(=O)C(F)(F)F]

TABLE 3

| Polymer | Monomer | Molar ratio | Pattern formation |
|---|---|---|---|
| P-1 | F_{PHA}/F_{CHO} | 1/1 | Confirmed |
| P-2 | F_{PHA}/F_{CHO} | 1/7 | Confirmed |
| P-3 | F_{PHA}/F_{DHP}/F_{tBFPC} | 1/1/1 | Confirmed |
| P-4 | F_{BPHA}/F_{CHO} | 1/5.58 | Confirmed |
| P-5 | F_{PHA}/F_{OTHPB}/F_{DHP} | 1/1.58/1.38 | Confirmed |
| P-6 | F_{PHA}/F_{SO} | 1/0.11 | Confirmed |
| P-7 | F_{PHA}/F_{THPO} | 1/0.59 | Confirmed |
| P-8 | F_{PHA}/F_{OTHPB}/F_{CEVE} | 1/2.4/4.3 | Confirmed |
| X-1 | F_{PHA} | 1 | Confirmed |

Referring to Table 3, it can be seen that polymers P-1 to P-8 are capable of forming patterns under conditions that are at least equivalent to those of polymer X-1.

Example embodiments of the inventive concepts may provide a resist composition having improved sensitivity and/or resolution.

It should be understood that example embodiments described herein should be considered in a descriptive sense only and not for purposes of limitation. Descriptions of features or aspects within each example embodiment should typically be considered as available for other similar features or aspects in other example embodiments. While some example embodiments have been described with reference to the figures, it will be understood by those of ordinary skill in the art that various changes in form and details may be made therein without departing from the spirit and scope as defined by the following claims.

What is claimed is:

1. A polymer, comprising:
a first repeating unit represented by Formula 1; and
a second repeating unit represented by Formula 2: 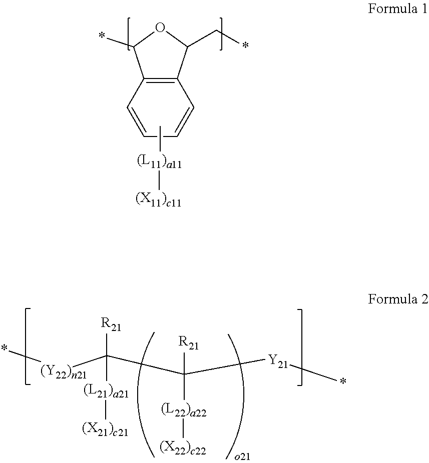
wherein in Formulae 1 and 2,
L₁₁ is a single bond; O; S; C(—O); C(—O)O; OC(—O); C(═O)NR₁₁; NR₁₁C(═O); S(═O); S(═O)₂O; OS(═O)₂; or a linear, branched or cyclic C₁-C₃₀ divalent hydrocarbon group optionally including a heteroatom,
a11 is an integer from 1 to 4,
R₁₁ is hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
X₁₁ is hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
c11 is an integer from 1 to 10,
Formula 1 optionally includes a plurality of X₁₁ based on c11 being greater than 1, adjacent two of the plurality of X₁₁ are optionally bound to each other to form a ring,
Y₂₁ is O, C(═O) or C(═O)O,
Y₂₂ is C(═O) or C(═O)O,
n21 is 0 or 1,
L₂₁ is a single bond; O; S; C(═O); C(═O)O; OC(═O); C(═O)NR₂₃; NR₂₃C(═O); S(═O); S(═O)₂O; OS(═O)₂; or a linear, branched or cyclic C₁-C₃₀ divalent hydrocarbon group optionally including a heteroatom,
L₂₂ is a single bond; O; S; C(═O); C(═O)O; OC(═O); C(═O)NR₂₄; NR₂₄C(═O); S(═O); S(═O)₂O; OS(═O)₂; or a linear, branched or cyclic C₁-C₃₀ divalent hydrocarbon group optionally including a heteroatom,
a21 and a22 are each independently an integer from 1 to 4,
R₂₁ to R₂₄, X₂₁, and X₂₂ are each independently hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
c21 and c22 are each independently an integer from 1 to 10,
Formula 2 optionally includes a plurality of X₂₁ based on c21 being greater than 1, Formula 2 optionally includes a plurality of X₂₂ based on c22 being greater than 1, and adjacent two of the plurality of X₂₁ and the plurality of X₂₂ are optionally bound to each other to form a ring,
o21 is 0 or 1, and
* is a bonding site with a neighboring atom.

2. The polymer of claim 1, wherein
L₁₁, L₂₁ and L₂₂ are each independently a single bond; O; S; C(═O); C(═O)O; OC(═O); C(═O) NH; NHC(═O); S(═O); S(═O)₂; S(═O)₂O; OS(═O)₂; a substituted or unsubstituted C₁-C₃₀ alkylene group; a substituted or unsubstituted C₃-C₃₀ cycloalkylene group; a substituted or unsubstituted C₃-C₃₀ heterocycloalkylene group; a substituted or unsubstituted C₂-C₃₀ alkenylene group; a substituted or unsubstituted C₃-C₃₀ cycloalkenylene group; a substituted or unsubstituted C₃-C₃₀ heterocycloalkenylene group; a substituted or unsubstituted C₆-C₃₀ arylene group; or a substituted or unsubstituted C₁-C₃₀ heteroarylene group.

3. The polymer of claim 1, wherein
R₂₁ and R₂₂ are each independently selected from hydrogen; deuterium; a halogen atom; a cyano group; a nitro group; a hydroxyl group; amino group; a carboxylate group; a thiol group; a C₁-C₂₀ alkyl group, a C₃-C₂₀ cycloalkyl group, and a C₆-C₂₀ aryl group,
the C₁-C₂₀ alkyl group, the C₃-C₂₀ cycloalkyl group, and the C₆-C₂₀ aryl group are each independently unsubstituted or substituted with deuterium, a halogen atom, a cyano group, a nitro group, a hydroxyl group, an amino group, a carboxylate group, a thiol group, an ester moiety, a sulfonate moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₃-C₂₀ cycloalkoxy group, a C₆-C₂₀ aryl group, or any combination thereof, and
R₁₁, R₂₃ and R₂₄ are each independently hydrogen, deuterium, a halogen atom, a cyano group, a nitro group, a hydroxyl group, amino group, a carboxylate group, a thiol group, a C₁-C₂₀ alkyl group, a C₁-C₂₀ halogenated alkyl group, a C₅-C₂₀ cycloalkyl group, or a C₆-C₂₀ aryl group.

4. The polymer of claim 1, wherein
X₁₁, X₂₁ and X₂₂ are each independently selected from hydrogen; deuterium; a halogen atom; a cyano group; a nitro group; a hydroxyl group; an amino group; a carboxylate group; a thiol group; a linear, branched or cyclic C₁-C₃₀ monovalent hydrocarbon group containing a polar moiety; and a linear, branched or cyclic C₁-C₃₀ monovalent hydrocarbon group not containing a polar moiety, and
the polar moiety is one or more selected from a halogen atom, a cyano group, a nitro group, a hydroxyl group, an amino group, a carboxylate group, a thiol group, O, C═O, a sultone moiety, a lactone moiety, an ester moiety, a sulfonate moiety, a carbonate moiety, a carbamate moiety, and a carboxylic anhydride moiety.

5. The polymer of claim 1, wherein
X₁₁, X₂₁ and X₂₂ are each independently selected from hydrogen; deuterium; a halogen atom; a cyano group; a nitro group; a hydroxyl group; an amino group; a carboxylate group; a thiol group; a C₁-C₁₀ alkyl group unsubstituted or substituted with deuterium, a halogen atom, a cyano group, nitro group, a hydroxyl group, an amino group, a carboxylate group, a thiol group, or any combination thereof; and groups represented by Formulae 5-1 to 5-19 below, 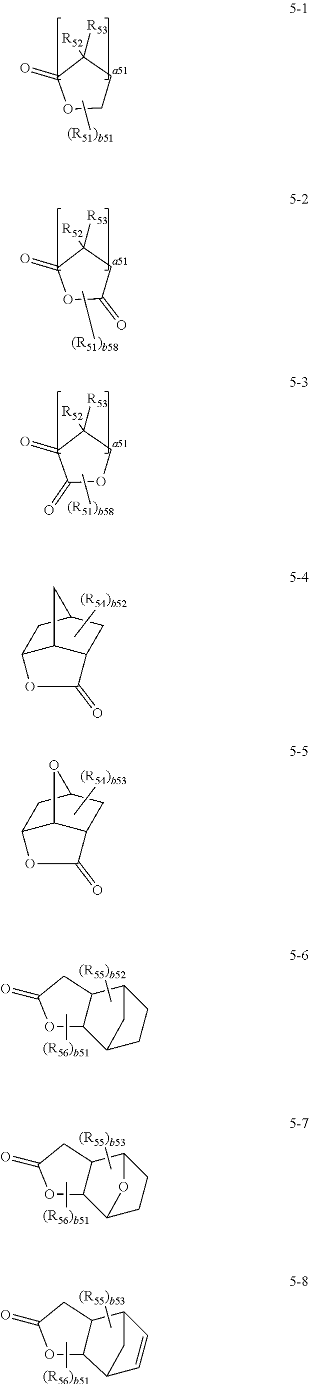 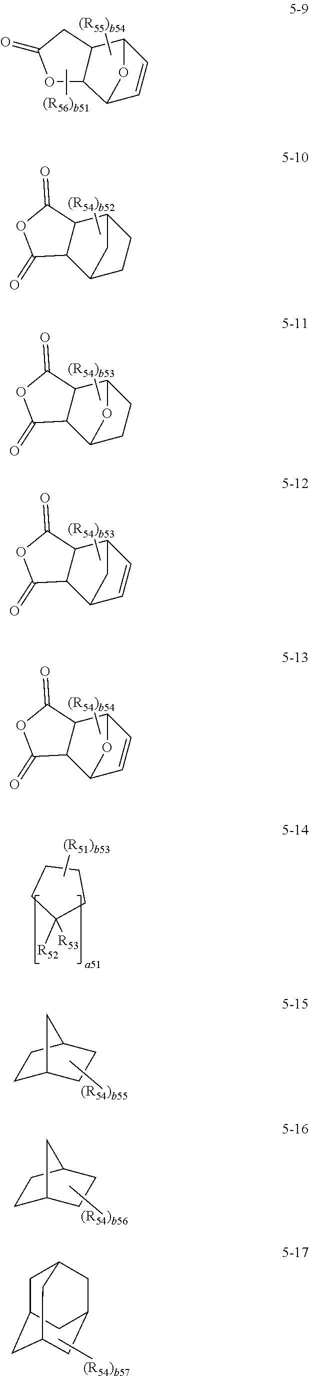 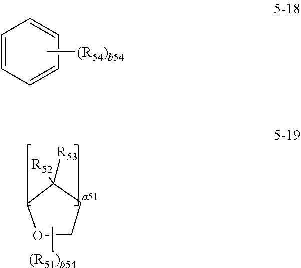
wherein in Formulae 5-1 to 5-19,
a51 is an integer from 1 to 3,
R₅₁ to R₅₆ are each independently a bonding site with a neighboring atom, hydrogen, deuterium, a halogen atom, a cyano group, a nitro group, a hydroxyl group, an amino group, a carboxylate group, a thiol group, or a linear, branched or cyclic C₁-C₁₀ monovalent hydrocarbon group optionally including a heteroatom,
one of R₅₁ to R₅₃, one of R₅₄, and one of R₅₅ or R₅₆ are each a bonding site with a neighboring atom,
b51 is an integer from 1 to 4,
b52 is an integer from 1 to 10,
b53 is an integer from 1 to 8,
b54 is an integer from 1 to 6,
b55 is an integer from 1 to 12,
b56 is an integer from 1 to 14,
b57 is an integer from 1 to 16, and
b58 is 1 or 2.

6. The polymer of claim 5, wherein
R₅₁ to R₅₆ are each independently selected from a bonding site with a neighboring atom, hydrogen, deuterium, a halogen atom, a cyano group, a nitro group, a hydroxyl group, an amino group, a carboxylate group, a thiol group, a C₁-C₁₀ alkyl group, a C₃-C₁₀ cycloalkyl group, a C₁-C₁₀ alkoxy group, a C₃-C₁₀ cycloalkoxy group and groups represented by Formulae 6-1 to 6-12 below, 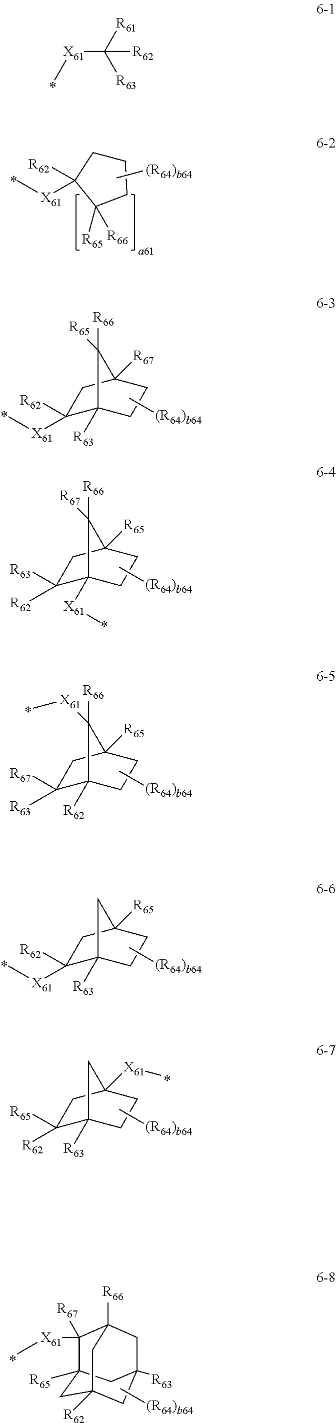 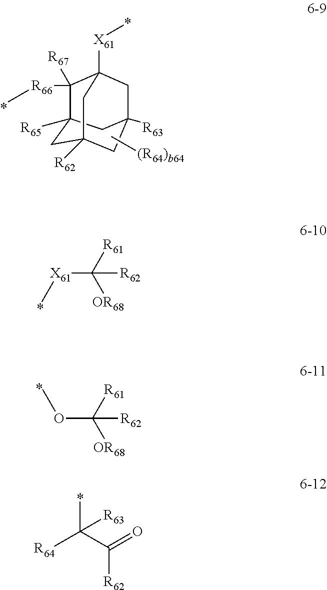
wherein in Formulae 6-1 to 6-12,
X₆₁ is an ester moiety, a sulfonate moiety, a carbonate moiety, or a carbamate moiety,
a61 is an integer from 1 to 3,
R₆₁ and R₆₈ are each independently a C₁-C₁₀ alkyl group, a C₃-C₁₀ cycloalkyl group, a C₁-C₁₀ alkoxy group, or a C₃-C₁₀ cycloalkoxy group,
R₆₂ to R₆₇ are each independently hydrogen, deuterium, a halogen atom, a cyano group, a nitro group, a hydroxyl group, an amino group, a carboxylate group, a thiol group, a C₁-C₁₀ alkyl group, a C₃-C₁₀ cycloalkyl group, a C₁-C₁₀ alkoxy group, or a C₃-C₁₀ cycloalkoxy group,
two adjacent groups of R₆₁ to R₆₈ are optionally bound to each other to form a ring,
b64 is an integer from 1 to 10, and
* is a bonding site with a neighboring atom.

7. The polymer of claim 1, wherein
the first repeating unit is selected from Group I, and
the second repeating unit is selected from Group II:

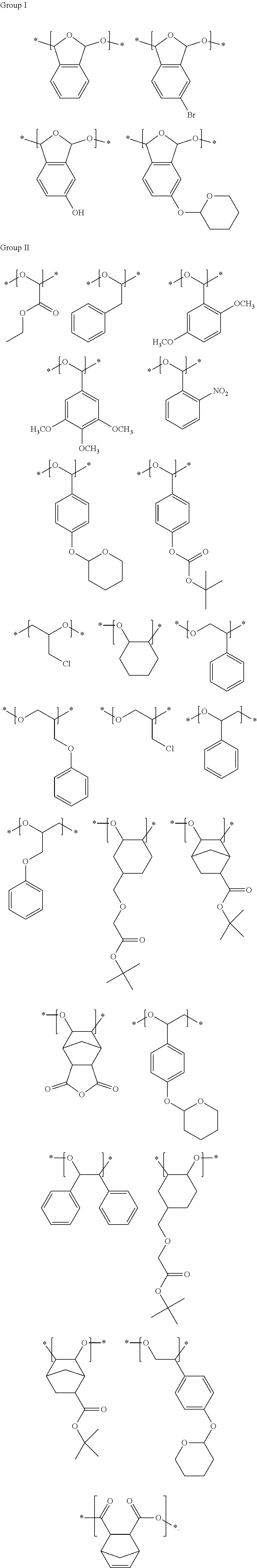

8. The polymer of claim 1,
further comprising a third repeating unit represented by Formula 3: 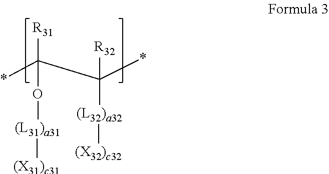
wherein in Formula 3,
L₃₁ is a single bond; O; S; C(═O); C(═O)O; OC(═O); C(═O)NR₃₃; NR₃₃C(═O); S(═O); S(═O)₂O; OS(═O)₂; or a linear, branched or cyclic C₁-C₃₀ divalent hydrocarbon group optionally including a heteroatom,
L₃₂ is a single bond; O; S; C(═O); C(═O)O; OC(═O); C(═O)NR₃₄; NR₄₃C(═O); S(═O); S(═O)₂O; OS(═O)₂; or a linear, branched or cyclic C₁-C₃₀ divalent hydrocarbon group optionally including a heteroatom,
a31 and a32 are each independently an integer from 1 to 4,
R₃₁ to R₃₄, X₃₁ and X₃₂ are each independently hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylate anhydride moiety; or a linear, branched or cyclic C₁-C₃₀ monovalent hydrocarbon group optionally including a heteroatom,
c31 and c32 are each independently an integer from 1 to 10,
Formula 3 optionally includes a plurality of X₃₁ based on c31 being greater than 1, Formula 3 optionally includes a plurality of X₃₂ based on c32 being greater than 1, and adjacent two of the plurality of X₃₁ and the plurality of X₃₂ are optionally bound to each other to form a ring, and
* is a bonding site with a neighboring atom.

9. The polymer of claim 8, wherein
the third repeating unit is selected from Group III:

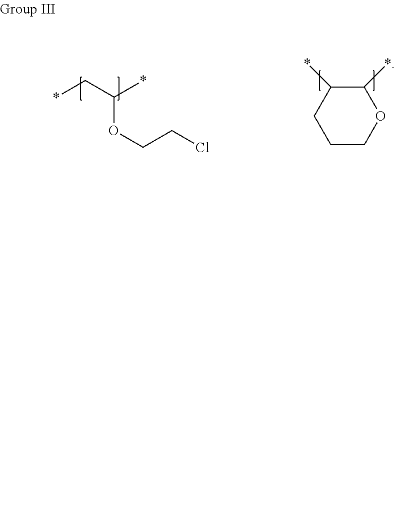

10. A method of producing a polymer, the method comprising:
polymerizing a mixture by using an acid catalyst, the mixture including a first monomer represented by Formula 1A, and at least one second monomer selected from an aldehyde, an oxirane, a carboxylic anhydride, and a lactone: 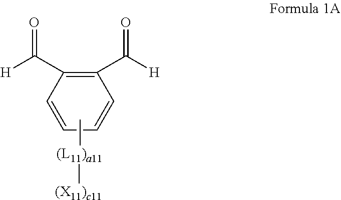
wherein in Formula 1A,
L₁₁ is a single bond; O; S; C(═O); C(═O)O; OC(═O); C(═O)NR₁₁; NR₁₁C(═O); S(═O); S(═O)₂O; OS(═O)₂; or a linear, branched or cyclic C₁-C₃₀ divalent hydrocarbon group optionally including a heteroatom,
a11 is an integer from 1 to 4,
R₁₁ is hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
X₁₁ is hydrogen; deuterium; a halogen atom; a cyano group; a nitro group; a hydroxyl group; an amino group; a carboxylate group; a thiol group; an ester moiety; a sulfonate moiety; a carbonate moiety; a lactone moiety; a sultone moiety; a carboxylic anhydride moiety; or a linear, branched or cyclic C₁-C₃₀ monovalent hydrocarbon group optionally including a heteroatom,
c11 is an integer from 1 to 10, and
Formula 1 optionally includes a plurality of X₁₁ based on c11 being greater than 1, adjacent two of the plurality of X₁₁ are optionally bound to each other to form a ring.

11. The method of claim 10, wherein
the mixture further comprises at least one third monomer selected from vinyl ethers.

12. The method of claim 10, wherein
the polymerizing further utilizes a RAFT agent.

13. A resist composition, comprising:
the polymer of claim 1; and
a solvent.

14. The resist composition of claim 13,
further comprising a photoacid generator.

15. The resist composition of claim 14,
wherein the photoacid generator is represented by Formula 7: 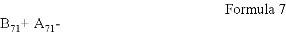
wherein in Formula 7,
B₇₁₊ is represented by Formula 7A, and A₇₁₋ is represented by any one of Formulae 7B to 7D, and
B₇₁₊ and A₇₁₋ are optionally linked via a carbon-carbon covalent bond, 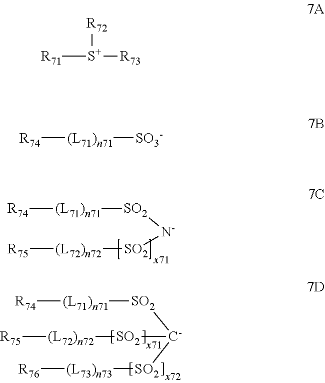
wherein in Formulae 7A to 7D,
L₇₁ to L₇₃ are each independently a single bond or CRR′,
R and R′ are each independently hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group or a C₃-C₃₀ cycloalkoxy group,
n71 to n73 are each independently 1, 2 or 3,
x71 and x72 are each independently 0 or 1,
R₇₁ to R₇₃ are each independently a linear, branched or cyclic C₁-C₃₀ monovalent hydrocarbon group optionally including a heteroatom, adjacent two of R₇₁ to R₇₃ are optionally bound to each other to form a condensed ring, and
R₇₄ to R₇₆ are each independently hydrogen; a halogen atom; or a linear, branched or cyclic C₁-C₃₀ monovalent hydrocarbon group optionally including a heteroatom.

16. The resist composition of claim 13,
further comprising a quencher.

17. The resist composition of claim 16,
wherein the quencher is represented by Formula 8: 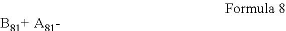
wherein in Formula 8,
B₈₁₊ is represented by any one of Formulae 8A to 8C, and A₈₁₋ is represented by any one of Formulae 8D to 8F,
B₈₁₊ and A₈₁₋ are optionally linked via a carbon-carbon covalent bond, 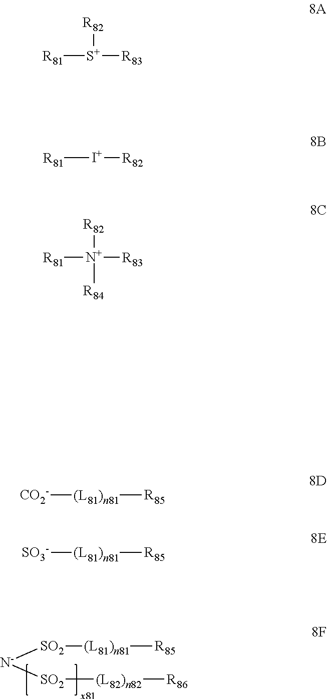
wherein in Formulae 8A to 8F,
L₈₁ and L₈₂ are each independently a single bond or CRR′,
R and R′ are each independently hydrogen, deuterium, a halogen atom, a cyano group, a hydroxyl group, a C₁-C₃₀ alkyl group, a C₁-C₃₀ halogenated alkyl group, a C₁-C₃₀ alkoxy group, a C₃-C₃₀ cycloalkyl group or a C₃-C₃₀ cycloalkoxy group,
n81 and n82 are each independently 1, 2 or 3,
x81 is 0 or 1,
R₈₁ to R₈₄ are each independently a linear, branched or cyclic C₁-C₃₀ monovalent hydrocarbon group optionally including a heteroatom,
adjacent two of R₈₁ to R₈₄ are optionally bound to each other to form a condensed ring, and
R₈₅ and R₈₆ are each independently hydrogen; a halogen atom; or a linear, branched or cyclic C₁-C₃₀ monovalent hydrocarbon group optionally including a heteroatom.

18. A method of forming a pattern, the method comprising:
applying the resist composition of claim 13 onto a substrate to form a resist film;
exposing at least a portion of the resist film to high-energy rays to form an exposed resist film; and
developing the exposed resist film based on using a developer.

19. The method of claim 18, wherein
the exposing is performed based on irradiating at least the portion of the resist film with at least one of ultraviolet rays, deep ultraviolet (DUV) rays, extreme ultraviolet (EUV) rays, X-rays, γ-rays, electron beams (EBs) or α particle beams.

20. The method of claim 18, wherein
the exposed resist film comprises an exposed portion and an unexposed portion, and
the exposed portion is removed during the developing.
